(19) United States
(12) Patent Application Publication
(10) Pub. No.: US 2026/0052977 A1
(43) Pub. Date: Feb. 19, 2026

(54) SEMICONDUCTOR DEVICE INCLUDING DUMMY MEMORY STRUCTURES, AND METHOD OF FABRICATING THE SAME

(71) Applicant: TAIWAN SEMICONDUCTOR MANUFACTURING COMPANY, LTD., Hsinchu (TW)

(72) Inventors: Chia-Ling LIU, Hsinchu (TW); Chia-En HUANG, Hsinchu (TW); Ming-jia LIANG, Hsinchu (TW); Tzu-Yu CHEN, Hsinchu (TW); Yao-Jen YANG, Hsinchu (TW); Ting-Wei CHIANG, Hsinchu (TW)

(21) Appl. No.: 18/808,511

(22) Filed: Aug. 19, 2024

(51) Int. Cl. H01L 23/528; H10B 61/00; H10N 50/01; H10N 50/10

(52) U.S. Cl. CPC H01L 23/5283; H10B 61/20; H10N 50/01; H10N 50/10

(57) ABSTRACT

A semiconductor device includes memory structures in wiring layers in a first region of a substrate, the memory structures including storage elements in the wiring layers, a peripheral circuit in a second region of the substrate, and dummy memory structures in the wiring layers in the second region and vertically overlapping the peripheral circuit.

### BACKGROUND

The semiconductor device industry has produced a wide variety of devices to address issues in a number of different areas. Some of these devices include structures for storing data. As semiconductor devices have become more complex, vertical integration has become increasingly attractive for reducing die sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view of a semiconductor device according to an embodiment, and FIG. 1B is a cross-sectional view corresponding to FIG. 1A.

FIG. 2A is a plan view of a semiconductor device according to an embodiment, and FIG. 2B is a cross-sectional view corresponding to FIG. 2A.

FIG. 3A is a plan view of a semiconductor device according to an embodiment, and FIG. 3B is a cross-sectional view corresponding to FIG. 3A.

FIG. 4 is a plan view of conductors in wiring layers in various regions of a semiconductor device according to an embodiment.

FIG. 5 is a plan view of conductor patterns in a semiconductor device according to some embodiments.

FIGS. 6-17 are plan views of arrangements of array regions and peripheral circuit regions in semiconductor devices according to some embodiments.

FIG. 18 is a plan view of a semiconductor device according to an embodiment.

FIG. 19A is a schematic cross-sectional view of resistor structures according to some embodiments.

FIG. 19B is a schematic cross-sectional view of resistor structures according to some embodiments.

FIG. 20 is a flowchart of a method of generating a layout and using the layout to manufacture a semiconductor device according to some embodiments.

FIG. 21 is a flowchart of a method of generating a layout according to an embodiment.

FIG. 22 is a flowchart of a method of fabricating one or more components of a semiconductor device according to an embodiment.

FIG. 23 is a block diagram of a semiconductor device according to an embodiment.

FIG. 24 is a block diagram of an electronic design automation (EDA) system according to some embodiments.

FIG. 25 is a block diagram of an integrated circuit manufacturing system, and a semiconductor device manufacturing flow associated therewith, according to some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Source/drain(s) may refer to a source or a drain, individually or collectively dependent upon the context.

A semiconductor device includes transistors in an active region of a substrate and interconnect layers over the active region to interconnect the transistors. In some semiconductor devices, storage elements of memory cells are provided in the interconnect layers, rather than in the substrate, to reduce an overall area of a die. In the interconnect layers, conductive structures, e.g., metal conductors, that form parts of the memory cells can have a different layout than conductive structures for other purposes, e.g., interconnections or other wiring. The differences in layouts can result in different area densities (pattern densities) of conductive structures, e.g., metal conductors, in the interconnect layers. The different area densities can prove challenging during a planarization operation such as chemical-mechanical polishing (CMP) by causing variations in material removal due to the different area densities across a wafer surface. Potential loading effects include dishing, erosion, unplanarized features, uneven feature thickness, and the like. The loading effects from the different area densities have the potential for undesirable consequences such as reduced process control, reduced yields, design constraints, and the like.

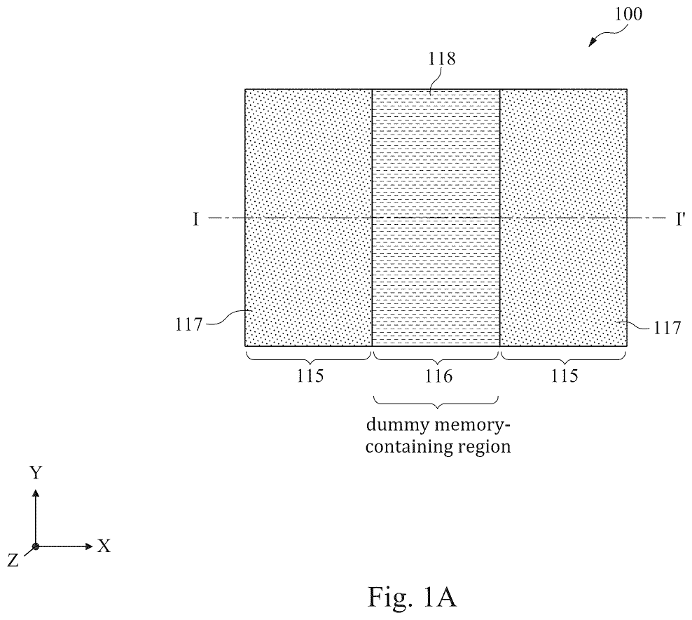

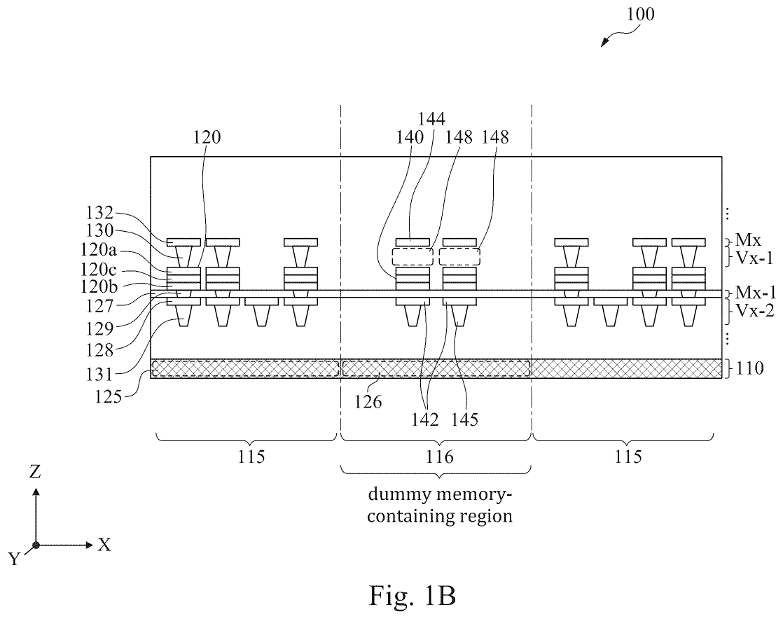

FIG. 1A is a plan view of a semiconductor device 100 according to an embodiment, and FIG. 1B is a cross-sectional view along a line I-I′ of FIG. 1A.

The semiconductor device 100 includes a substrate 110 having a first region 115 for a memory cell array 117 and a second region 116 for a peripheral circuit 118. The memory cell array has a plurality of memory structures each including a storage element 120. The first region 115 may be referred to as an array region. The memory cell array 117 is an embedded memory in some embodiments.

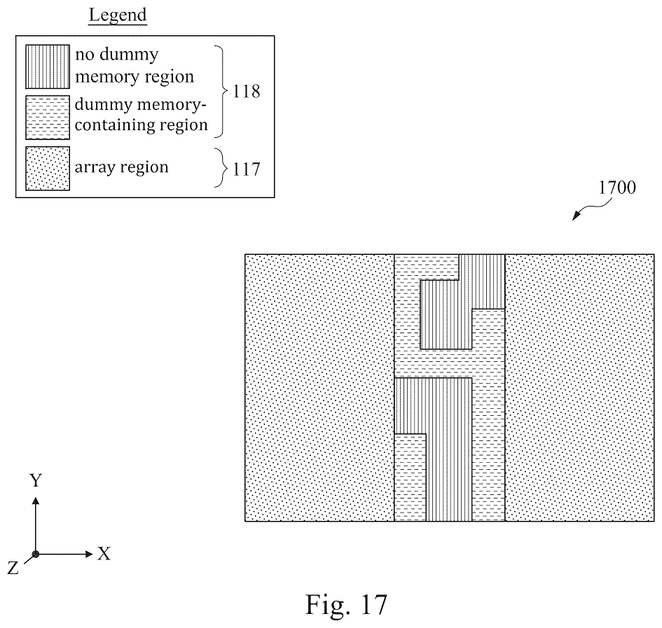

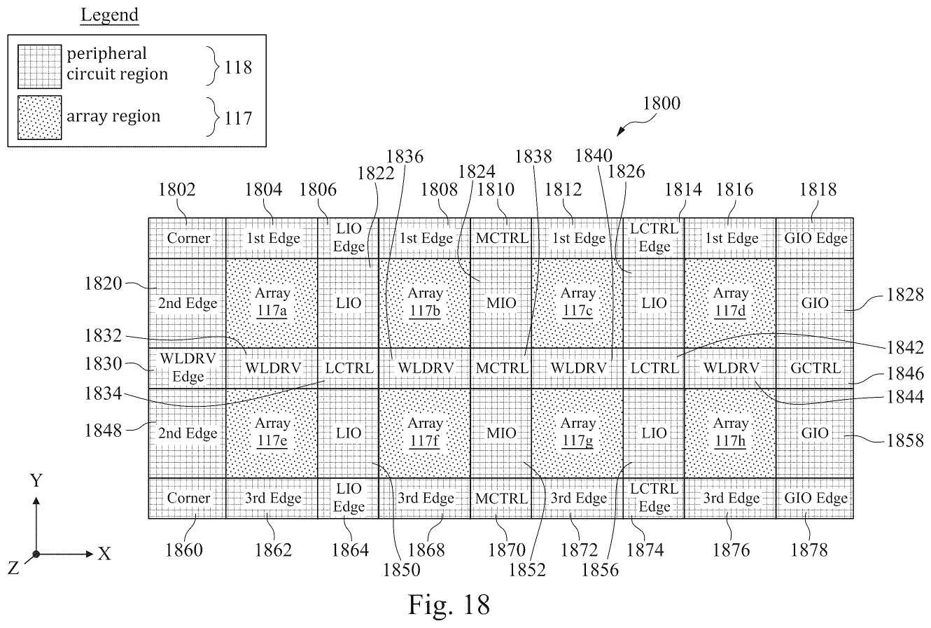

In FIGS. 1A-B, two array regions 115, each having a memory cell array 117, are present. In other embodiments, only a single array region 115 is present. In FIGS. 1A-B, the peripheral circuit 118 is between the two array regions 115. In other embodiments, the peripheral circuit 118 is adjacent to only one memory cell array 117, e.g., in a case of the peripheral circuit 118 being at an edge or outer region of the semiconductor device 100. In other embodiments, the peripheral circuit 118 has memory cell arrays 117 on three or four sides thereof. In other embodiments, the memory cell array 117 has peripheral circuits 118 on two, three, or four sides thereof. Additional arrangements are possible, some of which are described below in connection with FIG. 18.

The storage elements 120 are in wiring layers over the substrate 110. The storage elements 120 and wiring layers are formed by back-end of line (BEOL) fabrication operations. The storage elements 120 and the wiring layers formed in the BEOL operations may be referred to as BEOL structures. During the BEOL operations, front-end of line (FEOL) structures (e.g., transistors and the like) in the substrate 110 are also provided with interconnections, power and ground connections, connections to other substrates, or the like.

The BEOL structures include a wiring layer Mx and a wiring layer Mx-1 that is under the wiring layer Mx, i.e., between the wiring layer Mx and the substrate 110. The wiring layers Mx, Mx-1 are metal layers in some embodiments. The storage elements 120 are between the wiring layer Mx and the wiring layer Mx-1 in FIG. 1B. In some embodiments, one or more wiring layers are under the wiring layer Mx-1, i.e., between the wiring layer Mx-1 and the substrate 110. In some embodiments, one or more of wiring layers M0, M1, M2, M3, and the like are under the wiring layer Mx-1, where wiring layer MO is a first wiring layer over the substrate. In some embodiments, the wiring layer Mx-1 is an M4 wiring layer and the wiring layer Mx is an M5 wiring layer. In some embodiments, one or more wiring layers are present above the wiring layer Mx.

For ease of illustration, three storage elements 120 are shown in each array region 115 in FIG. 1B but it will be understood that the memory cell array 117 includes any suitable number of storage elements 120 in various embodiments.

In the substrate 110 in the array region 115, one or more transistors are provided to, e.g., control or access the storage elements 120. In some embodiments, each memory cell of the memory cell array 117 includes (i) at least one storage element 120 in the wiring layers in the array region 115 and (ii) at least one transistor in substrate 110 in the array region 115. The transistors of the memory cells may be referred to as access transistors and are collectively identified by reference numeral 125 in FIG. 1B. In FIG. 1B, the access transistors 125 are in the array region 115 and thus are vertically overlapped by the storage elements 120. A first element or region is considered to vertically overlap a second element or region when an imaginary line parallel to the Z-axis intersects both the first element or region and the second element or region. In some embodiments, the Z-axis is considered to be normal to a major surface of the substrate 110.

An example storage element 120 is a metal-insulator-metal (MIM) capacitor in which a first electrode 120a and a second electrode 120b have interposed therebetween a dielectric segment 120c.

In some embodiments, fabricating the storage elements 120 includes forming a base layer 127, e.g., an etch stop layer or the like, on the wiring layer Mx-1, patterning the base layer 127 to form openings in the base layer that vertically overlap conductors 128 in the wiring layer Mx-1, and forming conductive contacts 129 in the openings. To fabricate the storage elements as MIM capacitors, a metal layer corresponding to the second electrode 120b, a dielectric layer corresponding to the dielectric segment 120c, and another metal layer corresponding to the first electrode 120a are sequentially stacked, and then the stacked layers are patterned, e.g., using the base layer 127 as an etch stop layer, to form discrete storage elements 120 over the wiring layer Mx-1 and vertically overlapping the contacts 129. To provide a connection to the MIM capacitors, upper vias 130 are formed in a via layer Vx-1 to vertically overlap the first electrodes 120a, and conductors 132 are formed in the wiring layer Mx to vertically overlap the upper vias 130.

In some embodiments, the metal layers for the MIM capacitors, and thus the first and second electrodes 120a, 120b, include one or more of aluminum, titanium, titanium nitride, tantalum nitride, cobalt, silver, gold, copper, nickel, chromium, hafnium, ruthenium, tungsten, platinum, or the like. In some embodiments, the dielectric layer, and thus the dielectric segment 120c, include one or more of aluminum oxide, barium oxide, bismuth strontium tantalate (BST), calcium oxide, copper(I) oxide, hafnium oxide, hafnium silicon oxide, hafnium silicon oxynitride, Hf₁₋ₓ-ZrₓO₂ (HZO), lanthanum oxide, lead zirconate titanate (PZT), magnesium oxide, niobium(V) oxide, nickel(II) oxide, silicon carbide, silicon nitride, strontium bismuth tantalate (SBT), strontium oxide, strontium tantalate (ST), tantalum oxide, tantalum oxynitride, titanium oxide, yttrium oxide, zirconium oxide, or the like.

Structures, materials, and fabrication processes of the MIM memory cell are also disclosed in U.S. Pat. Nos. 11,581,368 and 10,553,672 which are incorporated by reference herein in their entireties.

In FIG. 1B, each of the storage elements 120 is a MIM capacitor, but in other embodiments the storage elements are other types of capacitors, variable resistance devices, or the like. For example, in some embodiments the storage elements 120 are resistive random-access memory (RRAM), magnetoresistive random-access memory (MRAM), phase change memory (PCM), or another BEOL-compatible storage element.

In some embodiments, the memory cells are RRAM cells that include resistive material layer, the resistance of which is changeable, e.g., to represent logic “0” or logic “1.” An example RRAM structure includes a first electrode, the resistive material layer, and a second electrode, the resistive material layer being between and in contact with the first and second electrodes. The RRAM structure is changeable among at least two states having respectively different resistance values, which correspond to different logical values. The RRAM structure is switched from one state to another (e.g., switched between a relatively higher resistance state and a relatively lower resistance state) by applying a predetermined voltage or current across the electrodes of the RRAM structure.

In some embodiments, the first and second electrodes of the RRAM cells include one or more of aluminum, copper, gold, iridium, platinum, ruthenium, tantalum, titanium, tungsten, or the like, or a boride, carbide, fluoride, nitride, oxide, or silicide thereof, or the like. Specific examples include TaN, TiAlN, TIN, TiW, indium tin oxide (ITO), and iridium-tantalum alloy. In some embodiments, the resistive material layer includes one or more of aluminum, cobalt, chromium, copper, iron, hafnium, molybdenum, nickel, ruthenium, silver, tin, tantalum, titanium, tungsten, zinc, zirconium, or the like, or a composite thereof with silicon. Specific examples include aluminum oxide, copper oxide, hafnium oxide, molybdenum oxide, nickel oxide, tantalum oxide, titanium oxide, tungsten oxide, zinc oxide, and zirconium oxide.

Structures, materials, and fabrication processes of the RRAM memory cell are also disclosed in U.S. Pat. Nos. 10,950,303, 9,431,604, and 9,299,927 which are incorporated by reference herein in their entireties.

In some embodiments, the memory cells are MRAM cells that include a magnetic tunnel junction (MTJ) structure as the storage element 120. An example MTJ structure includes a lower MTJ layer, an upper MTJ layer, and a nonmagnetic tunnel barrier layer between the lower MTJ layer and the upper MTJ layer. The nonmagnetic tunnel barrier layer is formed to have a thickness that allows electron tunneling through the nonmagnetic tunnel barrier layer. One of the lower MTJ layer and the upper MTJ layer is or includes a reference layer having a fixed magnetization direction. The other of the lower MTJ layer and the upper MTJ layer is or includes a free layer. The free layer is capable of existing in two stable magnetization directions, respectively parallel and antiparallel to the magnetization direction of the reference layer. Electrical resistance through the storage element 120 varies in accordance with the relative magnetic moments of the free and reference layers, and the magnetization direction of the free layer relative to the fixed magnetization direction of the reference layer. When the magnetization direction of the free layer is parallel to the fixed magnetization direction of the reference layer, the storage element 120 exhibits a relatively lower electrical resistance; when the magnetization direction of the free layer is antiparallel to the fixed magnetization direction of the reference layer, the storage element exhibits a relatively higher electrical resistance.

In some embodiments, the storage element 120 formed with the MTJ structure includes one or more additional layers such as a seed layer, a hard ferromagnetic layer, an antiferromagnetic coupling layer, a capping layer, or the like. For example, in some embodiments, the lower MTJ layer includes one or more of a seed layer, a hard ferromagnetic layer, an antiferromagnetic coupling layer, and the reference layer, and the upper MTJ layer includes a capping layer and the free layer. In other embodiments, the lower MTJ layer includes one or more of a capping layer and the free layer, and the upper MTJ layer includes one or more of an antiferromagnetic coupling layer, a hard ferromagnetic layer, and the reference layer.

In some embodiments, the nonmagnetic tunnel barrier layer includes one or more of aluminum nitride, aluminum oxide, aluminum oxynitride, hafnium oxide, magnesium oxide, zirconium oxide, or the like. In some embodiments, the reference layer includes a ferromagnetic material that provides a fixed magnetization direction such as one or more of cobalt, CoFe, CoFeB, CoFeNi, CoFeTa, CoPt, iron, FeB, molybdenum, NiFe, tantalum, tungsten, or the like. In some embodiments, the free layer includes a ferromagnetic material such as one or more of Co, CoFe, CoFeB, CoFeNi, CoFeTa, CoPt, Fe, FeB, NiFe, or the like. In some embodiments, the seed layer includes a polycrystalline nonmagnetic metallic material such as one or more of CoFeB alloy, NiFe alloy, ruthenium, titanium, or the like. In some embodiments, the hard ferromagnetic layer includes a ferromagnetic material such as one or more of cobalt, CoFe, CoNi, CoPd, CoPt, FeMn, iridium, IrMn, nickel, OsMn, palladium, platinum, PtMn, RhMn, ruthenium, or the like, and/or a bilayer stack of Co/Pt, Co/Pd, Co/Ni or the like. In some embodiments, the antiferromagnetic coupling layer includes an antiferromagnetic coupling material such as one or more of chromium, iridium, ruthenium, or the like. In some embodiments, the capping layer includes one or more of aluminum, aluminum nitride, aluminum oxide, aluminum oxynitride, chromium, copper, germanium, hafnium oxide, magnesium, magnesium oxide, molybdenum, molybdenum nitride, niobium, platinum, ruthenium, tantalum, titanium, titanium nitride, tungsten, zirconium, zirconium nitride, zirconium oxide, or the like. In some embodiments, electrodes disposed on opposite sides of the MTJ structure include a nonmagnetic metallic material such as one or more of aluminum, cobalt, copper, molybdenum, platinum, ruthenium, tantalum, tantalum nitride, titanium, titanium nitride, tungsten, tungsten nitride, or the like.

Structures, materials, and fabrication processes of the MRAM memory cell are also disclosed in U.S. Pat. Nos. 11,997,931 and 10,553,785 which are incorporated by reference herein in their entireties.

In some embodiments, the storage element 120 formed with the PCM structure includes a first electrode, a second electrode, and one or more layers of a PCM material between and in contact with the first and second electrodes. In some embodiments, a heating structure, to heat the PCM material layer(s), is positioned between or adjacent to the first and/or second electrodes. In a memory operation, a current is caused to flow through the PCM material based on an applied voltage, and a resistance value of the PCM structure is measured based on values of the applied voltage and current. Also, for sufficiently large values of the applied voltage, the current flowing through the PCM material and the heating structure (if present) induces self-heating, thereby causing an elevation in temperature to effect phase change in the PCM material. In some embodiments, a given phase configuration corresponds to a ratio of: (i) one or more volumes of the PCM material layer in a crystalline phase to (ii) one or more volumes of the PCM material layer in an amorphous phase. In some embodiments, a lowest value of the ratio corresponds to a smallest volume of the crystalline phase, and thereby a lowest conductance value of the PCM structure, and a highest value of the ratio corresponds to a largest volume of the crystalline phase and thereby a highest conductance value of the PCM structure. In some embodiments, the lowest ratio and conductance values correspond to a fully-amorphous PCM material layer, and highest ratio and conductance values correspond to a fully-crystalline PCM material layer. In some embodiments, the lowest ratio and conductance values correspond to at least a portion of the PCM material layer being in the crystalline phase, and/or the highest ratio and conductance values correspond to at least a portion of the PCM material layer being in the amorphous phase. The PCM material layer(s) transition, at least in part, between a low-resistance crystalline phase and a high-resistance amorphous phase based on one or more temperature values within a temperature range controlled by the applied voltage.

In some embodiments, the first and second electrodes of the PCM structure include one or more of aluminum, copper, tungsten, or the like. In some embodiments, the resistive material layer(s) include(s) one or more chalcogenide materials such as germanium-antimony-tellurium (GeSbTe or GST), GeTe, GeSb, Sb₂Te₃, or the like, which in some embodiments is/are doped with one or more of arsenic, carbon, gallium, indium, nitrogen, oxygen, selenium, silicon, tin, or the like.

Structures, materials, and fabrication processes of the PCM memory cell are also disclosed in U.S. Pat. No. 10,971,223 which is incorporated by reference herein in its entirety.

Additional embedded memories may be implemented as the memory cell array 117, e.g., memories using charge-based storage such as flash memory.

In the semiconductor device 100, the second region 116 of the substrate 110 includes circuitry that is different from that of the memory cell array 117. In some embodiments, the circuitry in the second region 116 is or includes the peripheral circuit 118. In some embodiments, the peripheral circuit 118 is configured to operate the memory cell array 117, e.g., to write data to or read data from the memory cell array 117, or to provide other functions such as input/output (I/O) related to the memory cell array 117. Examples of the peripheral circuit 118 include a word line driver, a local input-output (I/O) circuit, a main I/O circuit, a global I/O circuit, a local control circuit, a main control circuit, and the like. In other embodiments, the peripheral circuit 118 is a circuit adjacent to the memory cell array 117 while providing functions unrelated to the memory cell array 117.

In the second region 116, the peripheral circuit 118 includes peripheral circuit transistors 126 in the substrate 110. Also in the second region 116, interconnect wiring for the peripheral circuit transistors 126 vertically overlaps the peripheral circuit transistors 126, e.g., in wiring layers between the wiring layer Mx-1 and the substrate 110, to couple power, ground, signals, or the like to the peripheral circuit transistors 126.

As described above, in the first region 115, the storage elements 120 in FIG. 1B have conductors 128 in the wiring layer Mx-1 and conductors 132 in the wiring layer Mx. The storage element conductors (SEC) in the wiring layer Mx, i.e., the conductors 132 collectively, will be referred to as conductors SEC_Mx. The SEC in the wiring layer Mx-1, i.e., the conductors 128 collectively, will be referred to as conductors SEC_Mx-1.

Differences in area densities of the conductors in the wiring layer Mx between the first and second regions 115, 116 and/or differences in area densities of the conductors in the wiring layer Mx-1 between the first and second regions 115, 116 can result in loading effects in a planarization operation such as CMP. As a result, manufacturing defects may increase and yields may decrease. For example, uneven removal of a metal layer across a wafer may result in metal features being excessively removed to result in, e.g., open circuits or high resistance, or may result in metal remaining between adjacent conductors to result in, e.g., short circuits.

In some embodiments, one or more components (e.g., the storage element 120 and/or the conductors 128, 132 and vias 131) of the memory cells formed in the memory cell array 117 in the first region 115 are also formed in dummy memory cells in the second region 116. In FIG. 1B, a dummy storage element 140 in the second region 116 corresponds to the storage element 120 in the first region 115, a conductor 142 in the second region 116 corresponds to the conductor 128 in the first region 115, a conductor 144 in the second region 116 corresponds to the conductor 132 in the first region 115, and a via 145 in the second region 116 corresponds to the via 131 in the first region 115.

The inclusion of components such as the dummy storage element 140 and/or the conductors 142, 144 in the second region 116 allows for adjustments in area density differences between the first and second regions 115, 116 to reduce or mitigate loading effects, avoiding the use of additional masks or incurring additional process costs. In the semiconductor device 100, such components are included among other components of the peripheral circuit 118, i.e., such components are in addition to the components, wiring, and the like of the peripheral circuit 118, such that loading effects are reduced or mitigated while retaining the components, wiring, and the like of the peripheral circuit 118.

In FIG. 1B, the second region 116 includes dummy storage elements 140, corresponding conductors 142 below and vertically overlapping the dummy storage elements 140 in the wiring layer Mx-1, vias 145 under the conductors 142 in the via layer Vx-2, and corresponding conductors 144 above and vertically overlapping the dummy storage elements 140 in the wiring layer Mx. The dummy memory cells in the second region 116 thus each include a dummy storage element 140 between a conductor 144 in the wiring layer Mx and a conductor 142 in the wiring layer Mx-1.

The dummy memory storage element conductors (DSEC) in the wiring layer Mx, i.e., the conductors 144 collectively, will be referred to as conductors DSEC_Mx. The DSEC in the wiring layer Mx-1, i.e., the conductors 142 collectively, will be referred to as conductors DSEC_Mx-1.

The dummy memory cells including the dummy storage elements 140 and the conductors 142, 144 in the second region 116 effectively mimic the memory cells including the storage elements 120 and the conductors 128, 132 in the first region 115, and allow for control of relative metal area density in the second region 116 relative to the first region 115. The control of relative area densities enables layouts that reduce or mitigate loading effects.

In further detail, the inclusion of the dummy memory cells, and more particularly the inclusion of the conductors DSEC_Mx, DSEC_Mx-1, changes the relative area density of conductors in the wiring layers Mx, Mx-1 in the second region 116. In some embodiments, the number of dummy memory cells, and thus the number of the conductors DSEC_Mx, DSEC_Mx-1 in the second region 116, is controlled to thereby adjust relative area densities of conductors in the wiring layers Mx, Mx-1 between the first region 115 and the second region 116, which can be used to reduce or mitigate loading effects.

In some embodiments, the conductors DSEC_Mx are included in a number sufficient to tune or balance the relative area densities of conductors in the wiring layer Mx between the first region 115 and the second region 116. Stated differently, in some embodiments, the conductors DSEC_Mx are included in a number such that the area density of the conductors DSEC_Mx is tuned or balanced with the area density of the conductors SEC_Mx. That is, the combined area density of the conductors 144 is tuned or balanced with the area density of the conductors 132.

Similarly, in some embodiments, the conductors DSEC_Mx-1 are included in a number sufficient to tune or balance the relative area densities of conductors in the wiring layer Mx-1 between the first region 115 and the second region 116. Stated differently, in some embodiments, the conductors DSEC_Mx-1 are included in a number such that the area density of the conductors DSEC_Mx-1 is tuned or balanced with the area density of the conductors SEC_Mx-1. That is, the area density of the conductors 142 is tuned or balanced with the area density of the conductors 128.

In some embodiments, the conductors DSEC_Mx are included in a number such that the area density of the conductors DSEC_Mx is equal or about equal to the area density of the conductors SEC_Mx, and/or the conductors DSEC_Mx-1 are included in a number such that the area density of the conductors DSEC_Mx-1 is equal or about equal to the area density of the conductors SEC_Mx-1.

In some embodiments, the conductors DSEC_Mx are included in a number such that the area density of the conductors DSEC_Mx is less than the area density of the conductors SEC_Mx, and/or the conductors DSEC_Mx-1 are included in a number such that the area density of the conductors DSEC_Mx-1 is less than the area density of the conductors SEC_Mx-1.

In some embodiments, the conductors DSEC_Mx are included in a number such that the area density of the conductors DSEC_Mx is greater than the area density of the conductors SEC_Mx, and/or the conductors DSEC_Mx-1 are included in a number such that the area density of the conductors DSEC_Mx-1 is greater than the area density of the conductors SEC_Mx-1.

In the memory cell array 117 (first region 115), the upper vias 130 provide a connection to the storage elements 120. However, such vias are omitted in the dummy memory cells in the peripheral circuit 118 (second region 116), as indicated by dashed regions 148 in FIG. 1B. Thus, the dummy storage elements 140 are not connected to the conductors 144, thereby rendering the dummy storage elements 140 inoperative as a memory (and thus “dummy” memory cells).

Similarly, in the memory cell array 117 (first region 115), the contacts 129 provide a connection to the storage elements 120. However, such contacts are omitted in the dummy memory cells in the peripheral circuit 118 (second region 116). Thus, the dummy storage elements 140 are not connected to the conductors 142, thereby also rendering the dummy storage elements 140 inoperative as a memory (and thus “dummy” memory cells).

In some embodiments, the conductors 142 and/or 144, which are not connected to the dummy storage elements 140, are used for routing or wiring of other components of the semiconductor device 100, e.g., components of the peripheral circuit 118 or the like. In some embodiments, the conductors 142 and/or 144, which are not connected to the dummy storage elements 140, are used to provide power, ground, signals, or the like. In some embodiments, the conductors 142 and/or 144 form parts of structures other than memory cells, e.g., resistors or the like.

Although the semiconductor device 100 is shown in FIG. 1B as being free of vias between the dummy storage elements 140 and the conductors 144 (at regions 148), and as being free of contacts between the dummy storage elements 140 and the conductors 142, in other embodiments such vias and/or contacts are present to connect the dummy storage elements 140 and, instead, other vias, conductors, or components are omitted or disconnected to render the dummy storage elements 140 inoperative.

In FIG. 1B, three storage elements 120 are shown in each of the first regions 115, and two dummy storage elements 140 are shown in the second region 116. However, each of the first regions 115 can include any suitable number of storage elements 120, i.e., any suitable number of memory cells, and the second region can include any suitable number of dummy storage elements 140, i.e., any suitable number of dummy memory cells.

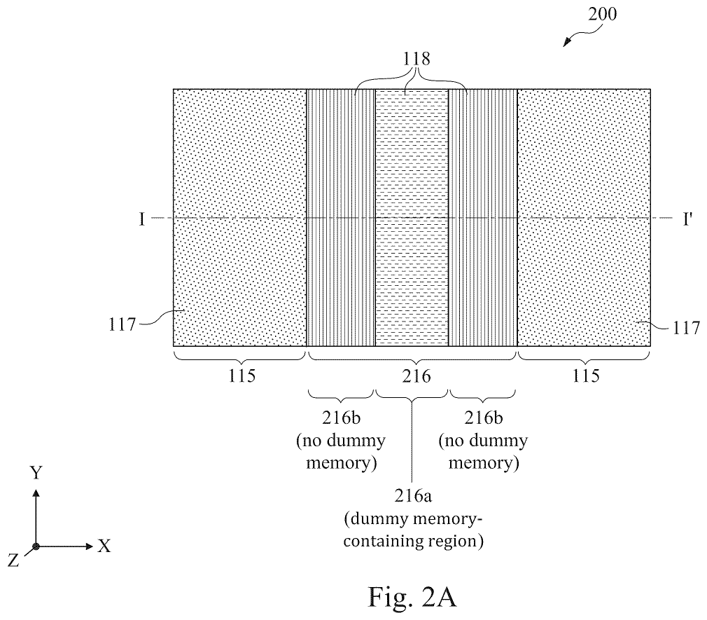

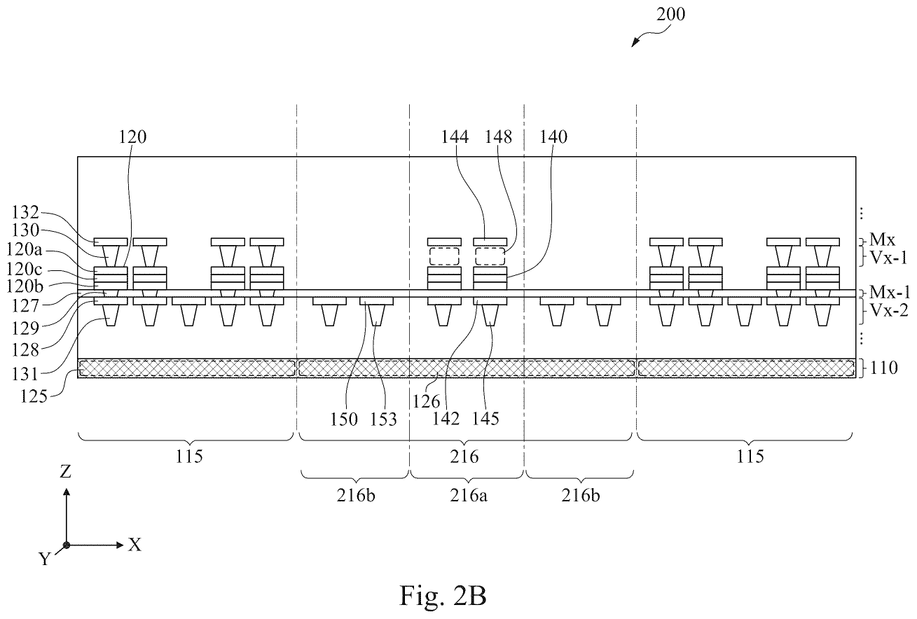

FIG. 2A is a plan view of a semiconductor device 200 according to an embodiment, and FIG. 2B is a cross-sectional view along a line I-I′ of FIG. 2A.

The semiconductor device 200 is similar to the semiconductor device 100 except that the semiconductor device 200 has a second region 216 in which a first sub-region 216a has the peripheral circuit 118 and dummy memory cells, and second sub-regions 216b have the peripheral circuit 118 and no dummy memory cells. In other words, whereas the second region 116 of FIGS. 1A-B includes the peripheral circuit 118 with the dummy memory cells arranged anywhere within the second region 116, the second region 216 of FIGS. 2A-B includes the peripheral circuit 118 in the first and second sub-regions 216a, 216b, and further includes the dummy memory cells arranged anywhere within the first sub-region 216a but not within the second sub-regions 216b. Thus, the peripheral circuit 118 has the dummy memory cells vertically overlapping the peripheral circuit transistors 126 in the first sub-region 216a but not in the second sub-regions 216b.

In the embodiment of FIGS. 2A-B, dummy storage elements 140 and conductors 144 in the wiring layer Mx are omitted in the second sub-regions 216b. The area density of conductors in the wiring layer Mx is therefore less in the second sub-regions 216b than in the first region 115 and the first sub-region 216a.

The second sub-regions 216b include conductors 150 in the wiring layer Mx-1, and include vias 153 in the via layer Vx-2. The area density of the conductors 150 in the wiring layer Mx-1 is controlled to reduce or mitigate loading effects when planarizing the wiring layer Mx-1. In various embodiments, the area density of the conductors 150 in the wiring layer Mx-1 is the same as, less than, or greater than the area density of the conductors 128 in the first region 115 and/or the area density of the conductors 142 in first sub-region 216a.

Although the semiconductor device 200 includes, in the second sub-regions 216b, the conductors 150 in the wiring layer Mx-1 and no conductors in the wiring layer Mx, in other embodiments conductors are also included in the wiring layer Mx in the second sub-regions 216b. In yet other embodiments, conductors are included in the wiring layer Mx in the second sub-regions 216b while the conductors 150 are omitted from the wiring layer Mx-1 in the second sub-regions 216b.

In a specific example in which the peripheral circuit is a word line driver for the memory cell array 117, the word line driver circuitry (including peripheral circuit transistors 126 in the substrate 110 in the second region 216, and interconnections in the wiring layers over the substrate in the second region 216) is arranged throughout the second region 216. In the first sub-region 216a, the word line driver circuitry is vertically overlapped by dummy memory cells including the dummy storage elements 140, corresponding conductors 142 below and vertically overlapping the dummy storage elements 140 in the wiring layer Mx-1, and corresponding conductors 144 above and vertically overlapping the dummy storage elements 140 in the wiring layer Mx. In the second sub-regions 216b, the word line driver circuitry is not overlapped by dummy storage elements 140 or conductors 144.

The semiconductor device 200 including the second sub-regions 216b allows for additional control of metal area density. The sizes, numbers, and placement of the second sub-regions 216b relative to those of the first region 115 and the first sub-region 216a can be controlled to provide a step arrangement in which no-dummy memory cell peripheral circuit regions (e.g., second sub-regions 216b) are mixed with memory cell array regions (e.g., first regions 115) and a dummy memory cell-containing peripheral circuit region (e.g., first sub-region 216a) to thereby control relative area densities in layers, e.g., wiring layers Mx, Mx-1, of the semiconductor device 200. This enables layouts that reduce or mitigate loading effects.

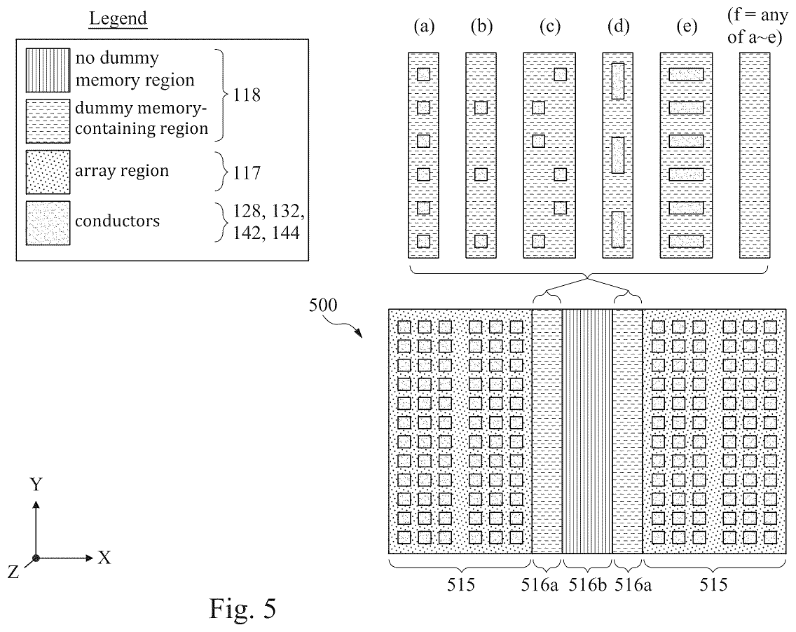

In FIGS. 2A-B, one first sub-region 216a is between two second sub-regions 216b relative to the X-axis. In other embodiments, the sub-regions are arranged in other ways, as described below in connection with FIGS. 5-16.

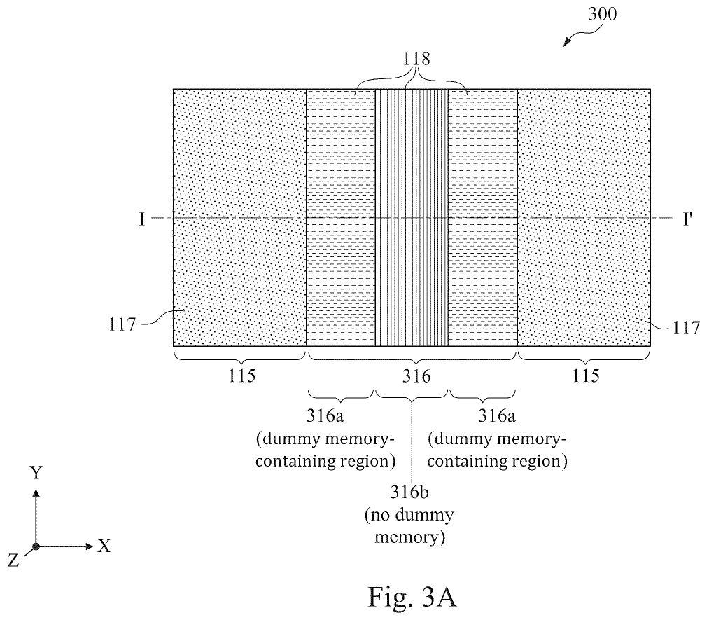

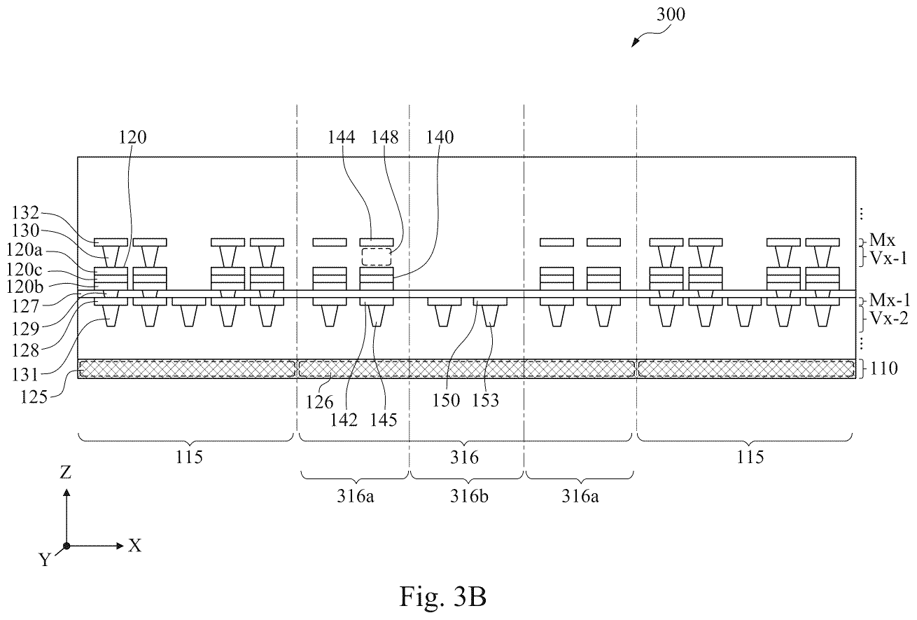

FIG. 3A is a plan view of a semiconductor device 300 according to an embodiment, and FIG. 3B is a cross-sectional view along a line I-I′ of FIG. 3A.

The semiconductor device 300 is similar to the semiconductor device 200 except that the semiconductor device 300 has a second region 316 in which two first sub-regions 316a have the peripheral circuit 118 and dummy memory cells, and a second sub-region 316b has the peripheral circuit 118 and no dummy memory cells. In FIGS. 3A-B, the second sub-region 316b is between the two first sub-regions 316a relative to the X-axis.

In FIGS. 3A-3B, the second region 316 includes the peripheral circuit 118 in the first sub-regions 316a and the second sub-region 316b, and further includes the dummy memory cells arranged anywhere within the first sub-regions 316a but not within the second sub-region 316b. Thus, the peripheral circuit 118 has the dummy memory cells vertically overlapping the peripheral circuit transistors 126 in the first sub-regions 316a but not in the second sub-region 316b.

In the embodiment of FIGS. 3A-B, dummy storage elements 140 and conductors 144 in the wiring layer Mx are omitted in the second sub-region 316b. The area density of conductors in the wiring layer Mx in the second sub-region 316b is therefore less than the area density of the conductors 132 in the first region 115 and less than the area density of the conductors 144 in the first sub-regions 316a. In the wiring layer Mx-1, the area density of the conductors 150 can be controlled to be the same as, greater than, or less than the area density of the conductors 128 in the first region 115 and/or the area density of the conductors 142 in the first sub-region 316a.

The semiconductor device 300 provides a step arrangement in which a no-dummy memory cell peripheral circuit region (e.g., second sub-region 316b) is mixed with memory cell array regions (e.g., first regions 115) and dummy memory cell-containing peripheral circuit regions (e.g., first sub-regions 316a) to thereby control relative area densities in layers, e.g., wiring layers Mx, Mx-1, of the semiconductor device 300. This enables layouts that reduce or mitigate loading effects.

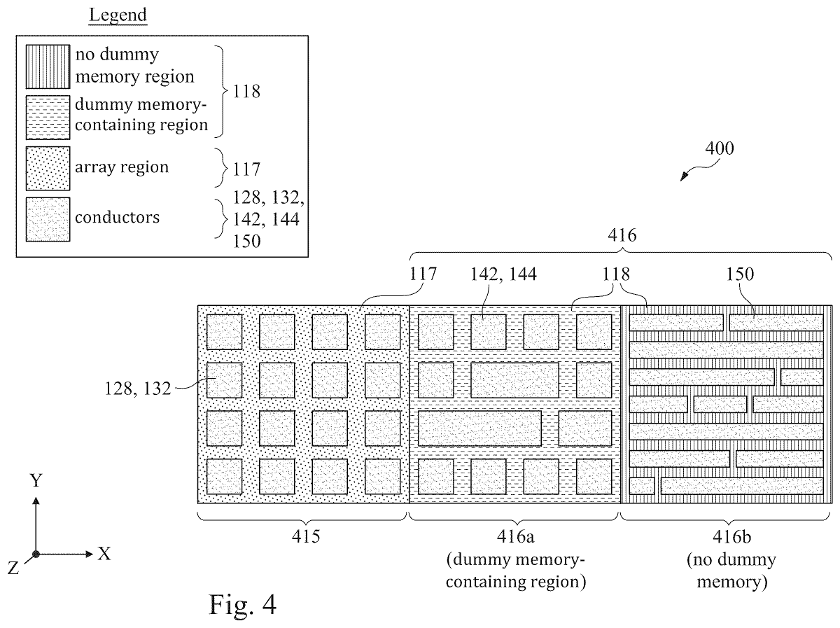

FIG. 4 is a plan view of conductors in wiring layers in various regions of a semiconductor device according to an embodiment.

In FIG. 4, an array region, a dummy memory cell-containing peripheral circuit region, and a no dummy cell peripheral circuit region each have different conductor patterns. The array region, denoted here as a first region 415, corresponds to the first region 115 and includes the memory cell array 117. The dummy memory cell-containing peripheral circuit region, denoted here as a first sub-region 416a, corresponds to the first sub-regions 216a, 316a. The no dummy cell peripheral circuit region, denoted here as a second sub-region 416b, corresponds to the second sub-regions 216b, 316b. The first and second sub-regions 416a, 416b collectively include the peripheral circuit 118.

In FIG. 4, the memory cell array 117 includes a regular array of four rows and four columns of conductors, which are the conductors 132 in the wiring layer Mx and/or the conductors 128 in the wiring layer Mx-1. The four rows and four columns are merely an example, and any suitable number of rows and/or columns of conductors can be included in other embodiments. The first region 115 has a first area density of conductors 132, 128 in the wiring layers Mx, Mx-1.

In the first sub-region 416a, the conductors 142 and/or 144 have a pattern similar to the four row, four column pattern of the memory cell array 117 except that two column-adjacent patterns are connected together in a bar shape in the second row, and the third row includes patterns that are longer in the X-axis direction than the conductors 132, 128 of the memory cell array 117. The first sub-region 416a has a second area density of conductors 132, 128 in the wiring layers Mx, Mx-1.

In the second sub-region 416b, the conductors 150 are generally row-shaped, extending parallel to the X-axis, and are shorter in the Y-axis direction such that seven rows of the conductors 150 are present as compared to four rows of the conductors 132, 128 in the memory cell array 117. The second sub-region 416b has a third area density of conductors 150 in the wiring layer Mx-1. In the second sub-region 416b, the area density of the conductors 150 in the wiring layer Mx-1 can be controlled to be the same as, greater than, or less than the area density of the conductors 128 in the first region 115 and/or the area density of the conductors 142 in the first sub-region 416a.

FIG. 5 is a plan view of conductor patterns in a semiconductor device 500 according to embodiments.

The semiconductor device 500 includes a first region 515 that corresponds to the first regions 115, 415, and includes the memory cell array 117. Two first sub-regions 516a and a second sub-region 516b (forming a second region 516) collectively include the peripheral circuit 118.

The first sub-regions 516a correspond to the first sub-regions 216a, 316a, 416a, and include dummy memory cells. Thus, the dummy storage elements 140, the conductors 144 in the wiring layer Mx, and the conductors 142 in the wiring layer Mx-1 vertically overlap the peripheral circuit transistors 126 of the peripheral circuit 118 in the first sub-region 516a.

The second sub-region 516b corresponds to the second sub-regions 216b, 316b, 416b, and does not include dummy memory cells. In some embodiments, the second sub-region 516b includes the conductors 150 in the wiring layer Mx-1 and includes the vias 153 in the via layer Vx-2, but does not include the dummy storage elements 140 or the conductors 144 in the wiring layer Mx.

In FIG. 5, six different conductor patterns a, b, c, d, e, and f are some examples of conductor patterns for wiring layers in the first sub-regions 516a, e.g., for the conductors 144 in the wiring layer Mx and/or for the conductors 142 in the wiring layer Mx-1. The various conductor patterns can be used for wiring or the like, beyond or in addition to existing wiring in the first sub-regions 516a that is devoted to the peripheral circuit 118. Thus, the six conductor patterns a˜f are some examples of wiring shapes that can be used for routing of device elements that are decoupled from the memory cell array 117, thereby providing additional functionality or routing flexibility in the semiconductor device 500 relative to a semiconductor device that does not include the dummy memory cells in the peripheral circuit 118.

The first conductor pattern ‘a’ for the conductors 142 and/or 144 is the same pattern as used for conductors 128 and/or 132 in the memory cells in the memory cell array 117.

The second conductor pattern ‘b’ is composed of conductors 142 and/or 144 having a same X-Y area as the conductors 128 and/or 132 in the memory cells in the memory cell array 117, while being arranged at a different pitch in one direction. In FIG. 5, the pitch in the Y-axis direction of the conductors 142, 144 in the second conductor pattern ‘b’ is greater than the pitch in the Y-axis direction of the conductors 128, 132 in the memory cell array 117. In some embodiments, the pitch in the X-axis direction of the conductors 142, 144 in the second conductor pattern ‘b’ is also greater than the pitch in the X-axis direction of the conductors 128, 132.

The third conductor pattern ‘c’ is composed of conductors 142 and/or 144 having a same X-Y area as the conductors 128 and/or 132, while being arranged in a randomized pitch in the Y-axis direction. In other embodiments, the pitch in the X-axis direction of the conductors 142, 144 in the third conductor pattern ‘c’ is also randomized.

The fourth conductor pattern ‘d’ is composed of conductors 142 and/or 144 having a same X-axis dimension as the conductors 128 and/or 132, while having an extended slot shape (or bar shape) in the Y-axis direction relative to the conductors 128, 132. In other embodiments, the X-axis dimension of the conductors 142, 144 is greater than or less than that of the conductors 128, 132.

The fifth conductor pattern ‘e’ is composed of conductors 142 and/or 144 having a same Y-axis dimension as the conductors 128 and/or 132, while having an extended row shape (or bar shape) in the Y-axis direction relative to the conductors 128, 132. In other embodiments, the Y-axis dimension of the conductors 142, 144 is greater than or less than that of the conductors 128, 132.

The sixth pattern ‘f’ can be composed of any combination of the first through fifth patterns a˜e. The various combinations of conductor patterns can be used for adaptable wiring layouts that provide routing flexibility in the semiconductor device 500, while at the same time reducing or mitigating loading effects.

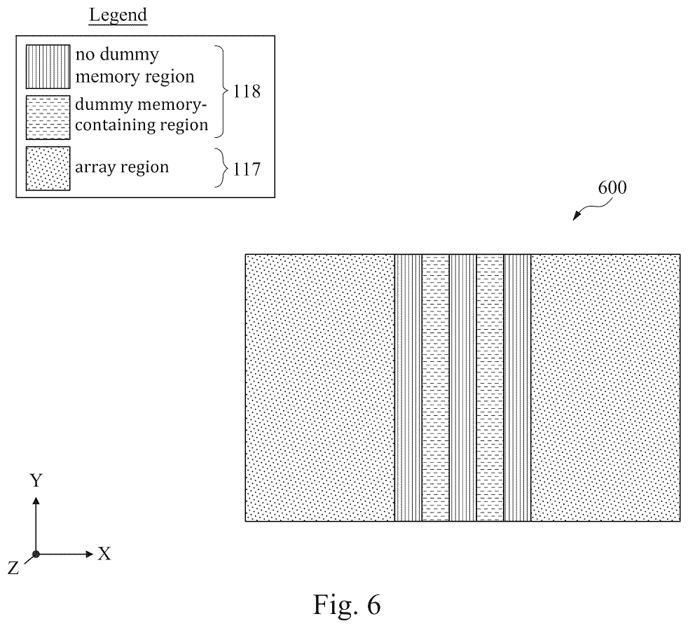

FIGS. 6-17 are plan views of arrangements of array regions and peripheral circuit regions in semiconductor devices 600˜1700 according to embodiments.

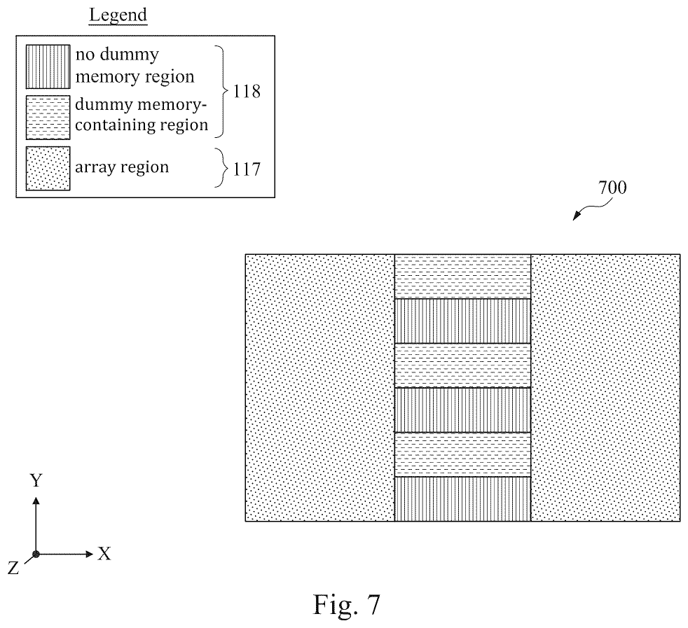

FIGS. 6 and 7 are examples of stripe-type arrangements of peripheral circuit regions. The arrangements in FIGS. 6 and 7 exemplify how the dummy memory cell-containing peripheral circuit regions and no dummy memory cell peripheral circuit regions can be mixed to provide routing flexibility while reducing or mitigating loading effects.

In FIG. 6, a semiconductor device 600 includes two array regions with a peripheral circuit region therebetween relative to the X-axis direction. In the peripheral circuit region, the peripheral circuit 118 is composed of two dummy memory cell-containing sub-regions (corresponding to the first sub-regions 216a, 316a, 416a, 516a of FIGS. 2A-5) and three sub-regions in which the dummy memory cells are not formed (corresponding to the second sub-regions 216b, 316b, 416b, 516b of FIGS. 2A-5). The sub-regions extend in the Y-axis direction and alternate in the X-axis direction. The semiconductor device 600 has mirror symmetry relative to an imaginary line parallel to the Y-axis and located at the center of the semiconductor device 600 relative to the X-axis. The semiconductor device 600 also has mirror symmetry relative to an imaginary line parallel to the X-axis and located at the center of the semiconductor device 600 relative to the Y-axis.

In FIG. 7, a semiconductor device 700 includes two array regions with a peripheral circuit region therebetween relative to the X-axis direction. In the peripheral circuit region, the peripheral circuit 118 is composed of three dummy memory cell-containing sub-regions (corresponding to the first sub-regions 216a, 316a, 416a, 516a of FIGS. 2A-5) and three sub-regions in which the dummy memory cells are not formed (corresponding to the second sub-regions 216b, 316b, 416b, 516b of FIGS. 2A-5). The sub-regions extend in the X-axis direction and alternate in the Y-axis direction. The semiconductor device 700 has mirror symmetry relative to an imaginary line parallel to the Y-axis and located at the center of the semiconductor device 700 relative to the X-axis.

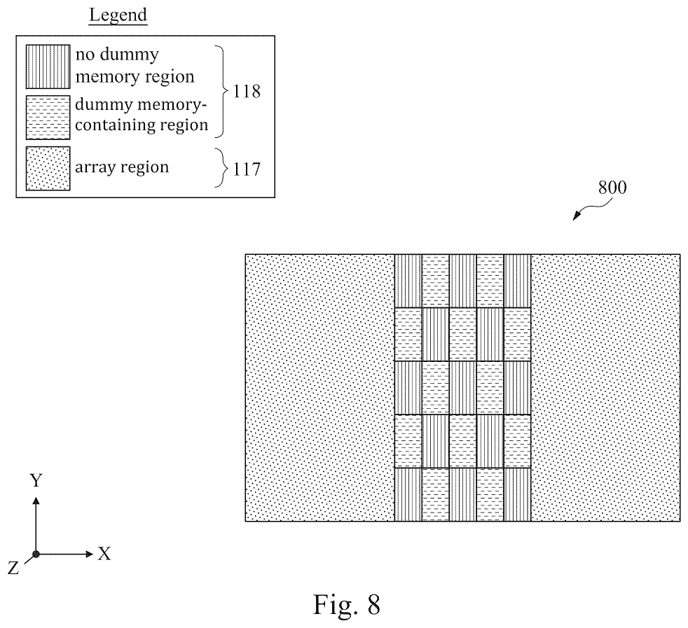

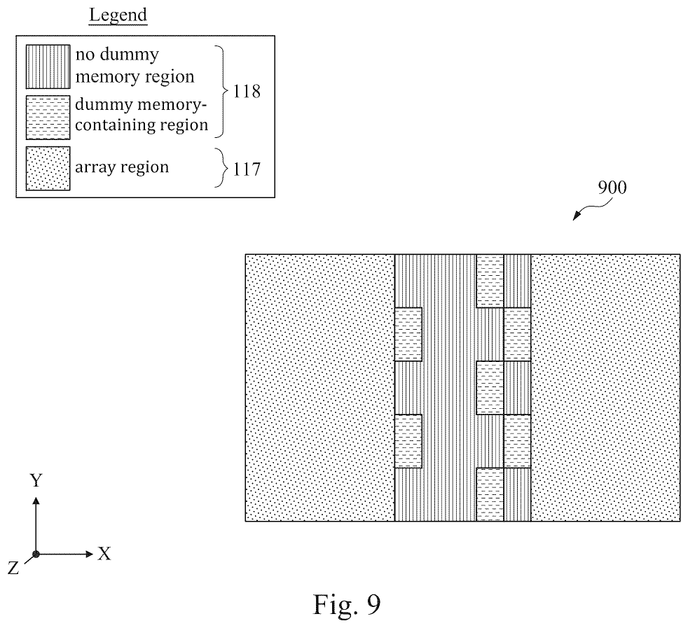

FIGS. 8 and 9 are examples of square-type arrangements of peripheral circuit regions. The arrangements in FIGS. 8 and 9 exemplify how the dummy memory cell-containing peripheral circuit regions and no dummy memory cell peripheral circuit regions can be mixed to provide routing flexibility while reducing or mitigating loading effects.

In FIG. 8, a semiconductor device 800 includes two array regions with a peripheral circuit region therebetween relative to the X-axis direction. In the peripheral circuit region, the peripheral circuit 118 is composed of twelve dummy memory cell-containing sub-regions (corresponding to the first sub-regions 216a, 316a, 416a, 516a of FIGS. 2A-5) and thirteen sub-regions in which the dummy memory cells are not formed (corresponding to the second sub-regions 216b, 316b, 416b, 516b of FIGS. 2A-5). The sub-regions are longer in the Y-axis direction than in the X-axis direction. The sub-regions have a 5×5 arrangement, and alternate in both X-axis and Y-axis directions. The semiconductor device 800 has mirror symmetry relative to an imaginary line parallel to the Y-axis and located at the center of the semiconductor device 800 relative to the X-axis. The semiconductor device 800 also has mirror symmetry relative to an imaginary line parallel to the X-axis and located at the center of the semiconductor device 800 relative to the Y-axis.

In FIG. 9, a semiconductor device 900 includes two array regions with a peripheral circuit region therebetween relative to the X-axis direction. In the peripheral circuit region, the peripheral circuit 118 is composed of seven dummy memory cell-containing sub-regions (corresponding to the first sub-regions 216a, 316a, 416a, 516a of FIGS. 2A-5) that are distributed in a sub-region in which the dummy memory cells are not formed (corresponding to the second sub-regions 216b, 316b, 416b, 516b of FIGS. 2A-5). The dummy memory cell-containing sub-regions are longer in the Y-axis direction than in the X-axis direction, and are arranged in alternating rows (in the X-axis direction) of one and two dummy memory cell-containing sub-regions. The semiconductor device 900 has mirror symmetry relative to an imaginary line parallel to the X-axis and located at the center of the semiconductor device 900 relative to the Y-axis.

The arrangements described above in connection with FIGS. 8 and 9 exemplify how multiple pairs of a dummy memory cell-containing peripheral circuit region and a no dummy memory cell peripheral circuit region can be arranged in a square-like patterns. In FIG. 8, a first row includes five peripheral circuit regions: two pairs of a dummy memory cell-containing peripheral circuit region and a no dummy memory cell peripheral circuit region, each arranged in a square-like pattern, and a single no dummy memory cell peripheral circuit region. A second row in FIG. 8 reverses the pattern of the first row. In FIG. 9, relative to FIG. 8, in second and third rows, one dummy memory cell-containing peripheral circuit is changed to a no dummy memory cell peripheral circuit region.

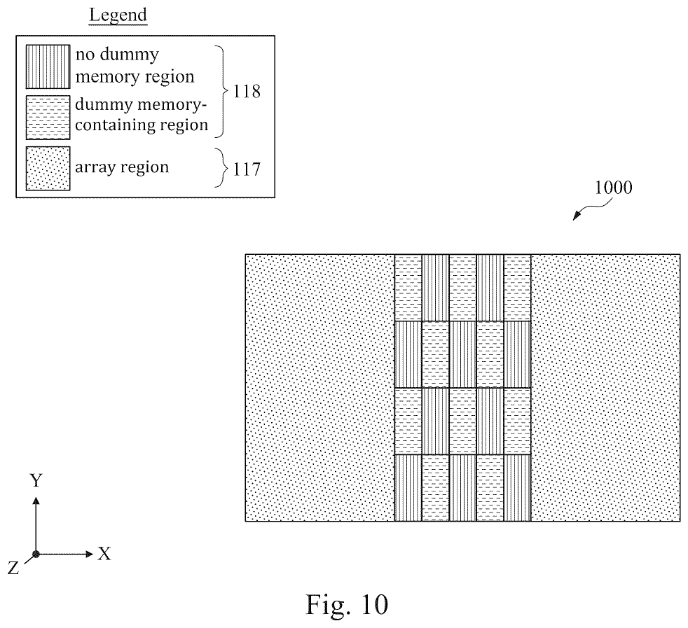

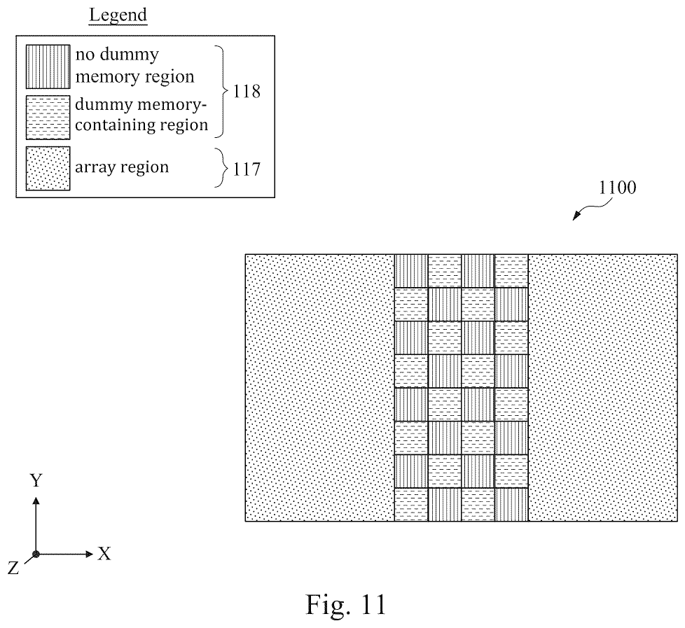

FIGS. 10 and 11 are examples of chessboard or checkerboard-type arrangements of peripheral circuit regions. The arrangements in FIGS. 10 and 11 exemplify how the dummy memory cell-containing peripheral circuit regions and no dummy memory cell peripheral circuit regions can be mixed to provide routing flexibility while reducing or mitigating loading effects.

In FIG. 10, a semiconductor device 1000 includes two array regions with a peripheral circuit region therebetween relative to the X-axis direction. In the peripheral circuit region, the peripheral circuit 118 is composed of ten dummy memory cell-containing sub-regions (corresponding to the first sub-regions 216a, 316a, 416a, 516a of FIGS. 2A-5) and ten sub-regions in which the dummy memory cells are not formed (corresponding to the second sub-regions 216b, 316b, 416b, 516b of FIGS. 2A-5). The sub-regions are longer in the Y-axis direction than in the X-axis direction. The sub-regions have a 5×4 arrangement (five rows (in the X-axis direction) and four columns (in the Y-axis direction)), and alternate in both X-axis and Y-axis directions. The semiconductor device 1000 has mirror symmetry relative to an imaginary line parallel to the Y-axis and located at the center of the semiconductor device 1000 relative to the X-axis. The semiconductor device 1000 is arranged in a layout like a chessboard or checkerboard.

In FIG. 11, a semiconductor device 1100 includes two array regions with a peripheral circuit region therebetween relative to the X-axis direction. In the peripheral circuit region, the peripheral circuit 118 is composed of sixteen dummy memory cell-containing sub-regions (corresponding to the first sub-regions 216a, 316a, 416a, 516a of FIGS. 2A-5) and sixteen sub-regions in which the dummy memory cells are not formed (corresponding to the second sub-regions 216b, 316b, 416b, 516b of FIGS. 2A-5). The sub-regions are longer in the Y-axis direction than in the X-axis direction. The sub-regions have an 8×4 arrangement (eight rows (in the X-axis direction) and four columns (in the Y-axis direction)), and alternate in both X-axis and Y-axis directions. The semiconductor device 1100 is arranged in a layout like a chessboard or checkerboard.

The arrangements described above in connection with FIGS. 10 and 11 exemplify how dummy memory cell-containing peripheral circuit regions and no dummy memory cell peripheral circuit regions can be arranged in a chessboard or checkerboard-like patterns. In FIG. 11, relative to FIG. 10, each peripheral circuit region has been further subdivided into a dummy memory cell-containing peripheral circuit and a no dummy memory cell peripheral circuit region.

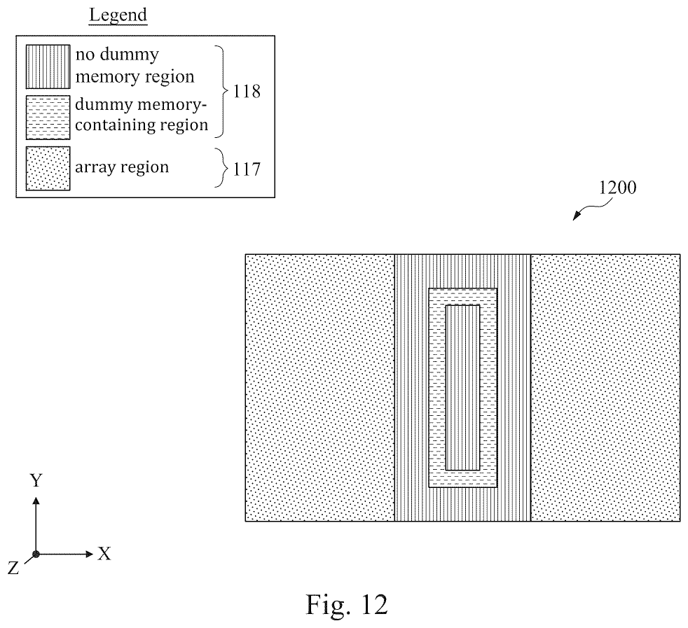

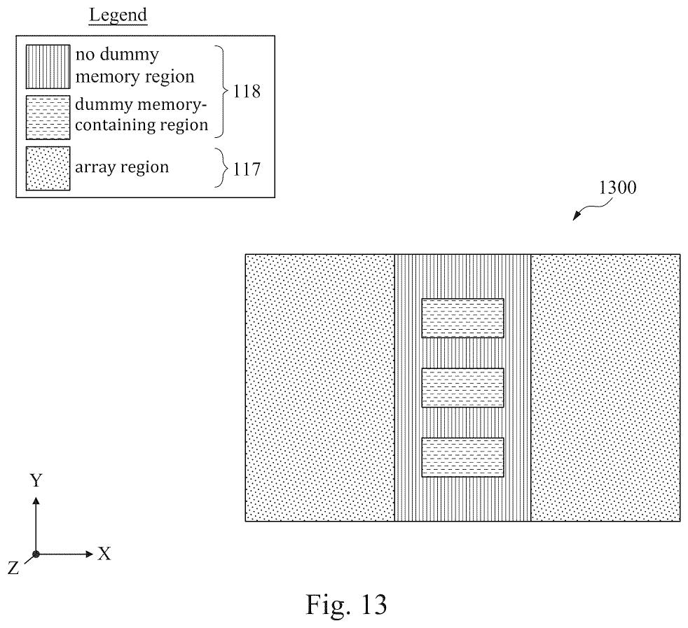

FIGS. 12 and 13 are examples of encirclement-type arrangements of peripheral circuit regions. The arrangements in FIGS. 12 and 13 exemplify how the dummy memory cell-containing peripheral circuit regions and no dummy memory cell peripheral circuit regions can be mixed to provide routing flexibility while reducing or mitigating loading effects.

In FIG. 12, a semiconductor device 1200 includes two array regions with a peripheral circuit region therebetween relative to the X-axis direction. In the peripheral circuit region, the peripheral circuit 118 is composed of a dummy memory cell-containing sub-region (corresponding to the first sub-regions 216a, 316a, 416a, 516a of FIGS. 2A-5) that surrounds one sub-region in which the dummy memory cells are not formed (corresponding to the second sub-regions 216b, 316b, 416b, 516b of FIGS. 2A-5), and that is surrounded by another sub-region in which the dummy memory cells are not formed. Thus, the three sub-regions have an encircling arrangement in which the dummy memory cell-containing sub-region encircles the one sub-region in which the dummy memory cells are not formed while being encircled by the other sub-region in which the dummy memory cells are not formed. The sub-regions are longer in the Y-axis direction than in the X-axis direction.

In FIG. 13, a semiconductor device 1300 includes two array regions with a peripheral circuit region therebetween relative to the X-axis direction. In the peripheral circuit region, the peripheral circuit 118 is composed of a three dummy memory cell-containing sub-regions (corresponding to the first sub-regions 216a, 316a, 416a, 516a of FIGS. 2A-5) that are spaced apart in the Y-axis direction and encircled by a continuous sub-region in which the dummy memory cells are not formed (corresponding to the second sub-regions 216b, 316b, 416b, 516b of FIGS. 2A-5). The semiconductor device 1300 has mirror symmetry relative to an imaginary line parallel to the Y-axis and located at the center of the semiconductor device 1300 relative to the X-axis. The semiconductor device 1300 also has mirror symmetry relative to an imaginary line parallel to the X-axis and located at the center of the semiconductor device 1300 relative to the Y-axis.

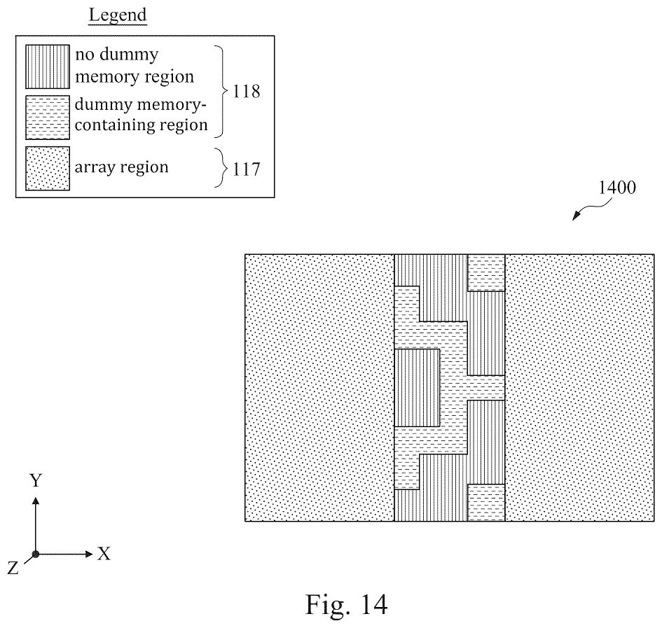

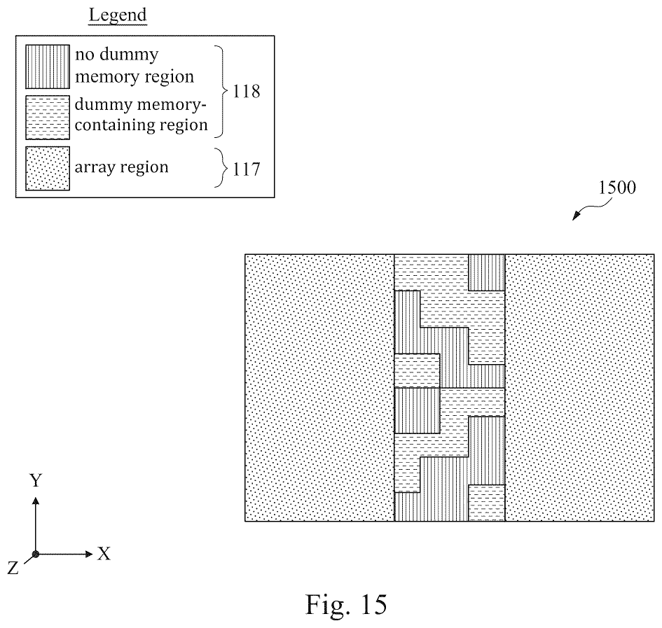

FIGS. 14 and 15 are examples of symmetric-type arrangements of peripheral circuit regions. The arrangements in FIGS. 14 and 15 exemplify how the dummy memory cell-containing peripheral circuit regions and no dummy memory cell peripheral circuit regions can be mixed to provide routing flexibility while reducing or mitigating loading effects.

In FIG. 14, a semiconductor device 1400 includes two array regions with a peripheral circuit region therebetween relative to the X-axis direction. In the peripheral circuit region, the peripheral circuit 118 is composed of three dummy memory cell-containing sub-regions (corresponding to the first sub-regions 216a, 316a, 416a, 516a of FIGS. 2A-5) and three sub-regions in which the dummy memory cells are not formed (corresponding to the second sub-regions 216b, 316b, 416b, 516b of FIGS. 2A-5). The semiconductor device 1400 has mirror symmetry relative to an imaginary line parallel to the X-axis and located at the center of the semiconductor device 1400 relative to the Y-axis.

In FIG. 15, a semiconductor device 1500 includes two array regions with a peripheral circuit region therebetween relative to the X-axis direction. In the peripheral circuit region, the peripheral circuit 118 is composed of four dummy memory cell-containing sub-regions (corresponding to the first sub-regions 216a, 316a, 416a, 516a of FIGS. 2A-5) and four sub-regions in which the dummy memory cells are not formed (corresponding to the second sub-regions 216b, 316b, 416b, 516b of FIGS. 2A-5). As compared to the semiconductor device 1400, the semiconductor device 1500 has inverse symmetry relative to an imaginary line parallel to the X-axis and located at the center of the semiconductor device 1500 relative to the Y-axis.

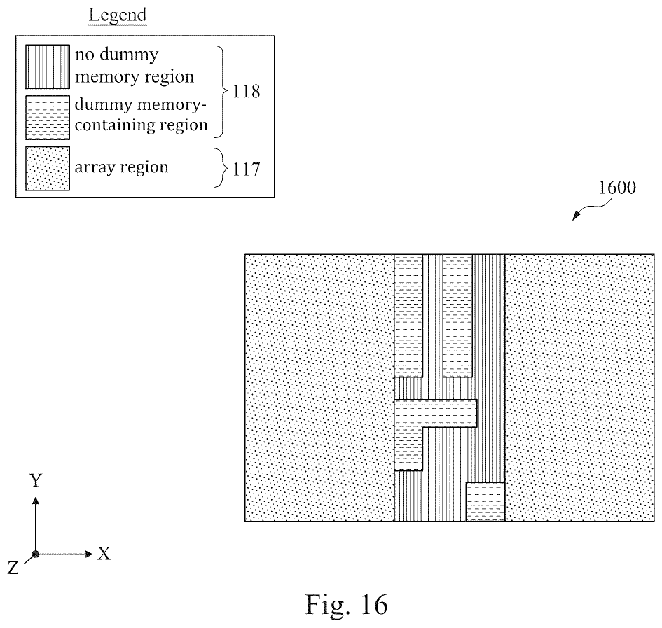

FIGS. 16 and 17 are examples of asymmetric-type arrangements of peripheral circuit regions. The arrangements in FIGS. 16 and 17 exemplify how the dummy memory cell-containing peripheral circuit regions and no dummy memory cell peripheral circuit regions can be mixed to provide routing flexibility while reducing or mitigating loading effects.

In FIG. 16, a semiconductor device 1600 includes two array regions with a peripheral circuit region therebetween relative to the X-axis direction. In the peripheral circuit region, the peripheral circuit 118 is composed of four dummy memory cell-containing sub-regions (corresponding to the first sub-regions 216a, 316a, 416a, 516a of FIGS. 2A-5) and one sub-region in which the dummy memory cells are not formed (corresponding to the second sub-regions 216b, 316b, 416b, 516b of FIGS. 2A-5). The sub-regions are arranged asymmetrically.

In FIG. 17, a semiconductor device 1700 includes two array regions with a peripheral circuit region therebetween relative to the X-axis direction. In the peripheral circuit region, the peripheral circuit 118 is composed of two dummy memory cell-containing sub-regions (corresponding to the first sub-regions 216a, 316a, 416a, 516a of FIGS. 2A-5) and two sub-regions in which the dummy memory cells are not formed (corresponding to the second sub-regions 216b, 316b, 416b, 516b of FIGS. 2A-5). The sub-regions are arranged asymmetrically.

In FIGS. 6-17, the peripheral circuit 118 is between two memory cell arrays 117 relative to the X-axis direction. In other embodiments, the number of memory cell arrays 117 in the semiconductor device is less than two or greater than two. In various embodiments, the memory cell array 117 is bounded on one, two, three, or four sides by one or more peripheral circuits 118. In other embodiments, the peripheral circuit 118 is bounded on one, two, three, or four sides by one or more memory cell arrays 117.

As described above in connection with FIGS. 1A-17, the memory cell array 117 is formed in a first region, e.g., the first regions 115, 415, 515, and the peripheral circuit 118 is formed in a second region, e.g., the second regions 116, 216, 316, 416, 516. In some embodiments, the second region includes a first sub-region, e.g., the first sub-regions 216a, 316a, 416a, 516a, in which dummy memory cells are formed along with the peripheral circuit, and includes a second sub-region, e.g., the second sub-regions 216b, 316b, 416b, 516b, in which dummy memory cells are not formed. An area ratio of the first sub-region to the second sub-region is selected to adjust a layout of the semiconductor device. The area ratio is selected to adjust, or tune, the relative areas of the sub-regions of the peripheral circuit 118. The area ratio can be from 100:0 to 0:100.

For example, in the semiconductor device 200, the area (in plan view, i.e., the X-Y plane) of the first sub-region 216a relative to the area of the second sub-regions 216b (i.e., the combined or total area of the second sub-regions) is approximately equal, i.e., the area ratio of the first sub-region to the second sub-regions, 216a: 216b, is approximately 50:50. In other embodiments, the area ratio can be increased to 100:0, such that the peripheral circuit 118 is entirely dummy memory cell containing, or decreased to 0:100, such that the peripheral circuit 118 is entirely free of dummy memory cells. In the former, the character of the conductor layers is more array-like, i.e., the planarization characteristics of the second region are more like the planarization characteristics of the memory cell array 117. In the latter, the character of the conductor layers is more logic-like, i.e., the planarization characteristics of the second region are more like planarization characteristics of a logic circuit region.

In general, the former case will tend to simplify or improve planarization, e.g., by yielding more uniform CMP, while the latter case will tend to simplify or improve routing by allowing more flexibility in the layout of conductors in the wiring layers. Semiconductor devices according to embodiments thus enable a flexible approach to design by allowing for tuning of the area ratio of dummy memory cell-containing peripheral circuit area to non-dummy memory cell-containing peripheral circuit area.

Moreover, the relative numbers, sizes, shapes, and placements of the first and second sub-regions, e.g., as in the examples of FIGS. 6-17, can be freely and widely varied so as to provide a desired tuning or balance of planarization characteristics (to reduce or mitigate loading effects) relative to layout or routing flexibility.

FIG. 18 is a plan view of a semiconductor device 1800 according to an embodiment.

The semiconductor device 1800 includes eight array regions respectively including memory cell arrays 117a˜h in a 4×2 arrangement surrounded by peripheral circuits 118. The peripheral circuits 118 include a word line driver (WLDRV) circuit, a local input-output (I/O) (LIO) circuit, a main I/O (MIO) circuit, a global I/O (GIO) circuit, a local control (LCTRL) circuit, a global control (GCTRL) circuit, and a main control (MCTRL) circuit.

Any one or more of the peripheral circuits 118 of the semiconductor device 1800 can be arranged as for the peripheral circuits 118 in FIGS. 1A-17. Also, any one or more of the peripheral circuits 118 of the semiconductor device 1800 can include first sub-regions that include dummy memory cells (corresponding to the first sub-regions 216a, 316a, 416a, 516a of FIGS. 2A-5) and second sub-regions in which the dummy memory cells are not formed (corresponding to the second sub-regions 216b, 316b, 416b, 516b of FIGS. 2A-5). The first and second sub-regions of the peripheral circuits 118 can be arranged as shown in FIGS. 2A-17.

In the semiconductor device 1800, the first memory cell array 117a is surrounded by a corner region 1802, a first edge region 1804, an LIO edge region 1806, a LIO circuit region 1822, a LCTRL circuit region 1834, a WLDRV circuit region 1832, a WLDRV edge region 1830, and a second edge region 1820.

The second memory cell array 117b is surrounded by the LIO edge region 1806, a first edge region 1808, a MCTRL circuit region 1810, an MIO circuit region 1824, a MCTRL circuit region 1838, a WLDRV circuit region 1836, the LCTRL circuit region 1834, and the LIO circuit region 1822. The second memory cell array 117b is aligned along the X-axis direction with the first memory cell array 117a.

The third memory cell array 117c is surrounded by the MCTRL circuit region 1810, a first edge region 1812, a LCTRL edge region 1814, an LIO circuit region 1826, a LCTRL circuit region 1842, a WLDRV circuit region 1840, the MCTRL circuit region 1838, and the MIO circuit region 1824. The third memory cell array 117c is aligned along the X-axis direction with the first memory cell array 117a.

The fourth memory cell array 117d is surrounded by the LCTRL edge region 1814, a first edge region 1816, a GIO edge region 1818, a GIO circuit region 1828, a GCTRL circuit region 1846, a WLDRV circuit region 1844, the LCTRL circuit region 1842, and the LIO circuit region 1826. The fourth memory cell array 117d is aligned along the X-axis direction with the first memory cell array 117a.

The fifth memory cell array 117e is surrounded by the WLDRV edge region 1830, the WLDRV circuit region 1832, the LCTRL circuit region 1834, an LIO circuit region 1850, an LIO edge region 1864, a third edge region 1862, a corner region 1860, and a second edge region 1848. The fifth memory cell array 117e is aligned along the Y-axis direction with the first memory cell array 117a.

The sixth memory cell array 117f is surrounded by the LCTRL circuit region 1834, the WLDRV circuit region 1836, the MCTRL circuit region 1838, an MIO circuit region 1852, an MCTRL circuit region 1870, a third edge region 1868, the LIO edge region 1864, and the LIO circuit region 1850. The sixth memory cell array 117f is aligned along the Y-axis direction with the second memory cell array 117b and is aligned along the X-axis direction with the fifth memory cell array 117e.

The seventh memory cell array 117g is surrounded by the MCTRL circuit region 1838, the WLDRV circuit region 1840, the LCTRL circuit region 1842, an LIO circuit region 1856, a LCTRL edge region 1874, a third edge region 1872, the MCTRL circuit region 1870, and the MIO circuit region 1852. The seventh memory cell array 117g is aligned along the Y-axis direction with the third memory cell array 117c and is aligned along the X-axis direction with the fifth memory cell array 117e.

The eighth memory cell array 117h is surrounded by the LCTRL circuit region 1842, the WLDRV circuit region 1844, the GCTRL circuit region 1846, a GIO circuit region 1858, a GIO edge region 1878, a third edge region 1876, the LCTRL edge region 1874, and the LIO circuit region 1856. The eighth memory cell array 117h is aligned along the Y-axis direction with the fourth memory cell array 117d and is aligned along the X-axis direction with the fifth memory cell array 117e.

In some embodiments, one or more of the peripheral circuit regions surrounding each of the memory cell arrays 117a˜h are implemented with dummy memory cells in BEOL layers of dummy memory cell-containing regions, to help tune or balance CMP loading in the arrays and the surrounding peripheral circuits and/or provide routing flexibility using the conductors associated with the dummy memory cells, e.g., the dummy memory cell conductors in the Mx, Mx-1 wiring layers.

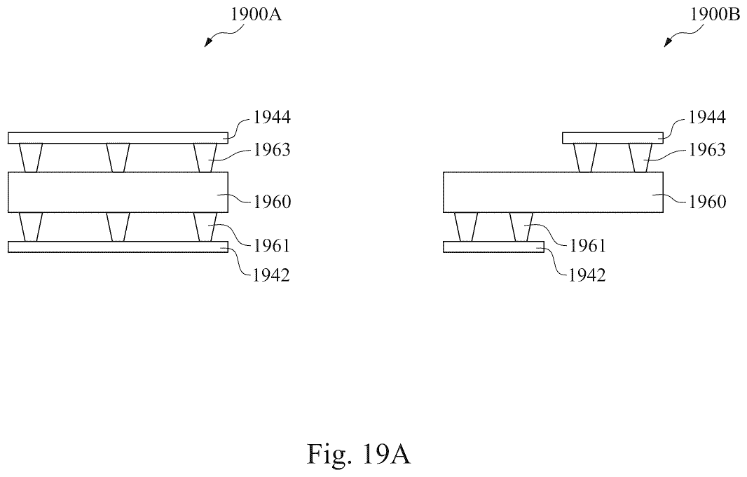

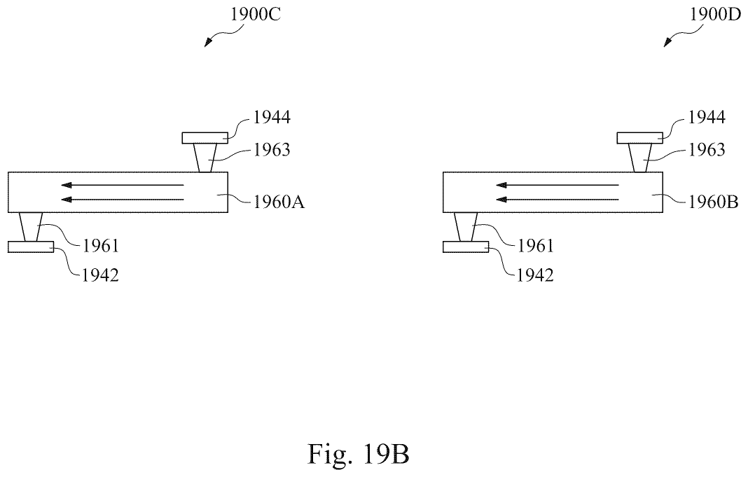

FIG. 19A is a schematic cross-sectional view of resistor structures 1900A and 1900B according to some embodiments.

As described above in connection with FIGS. 1B, 2B, and 3B, semiconductor devices according to some embodiments include peripheral circuit regions in which dummy memory cells are formed, the dummy memory cells including a dummy storage element 140 and conductors 142, 144. In some embodiments, the dummy storage elements 140 form parts of resistor structures in BEOL layers.

For example, in the resistor structure 1900A, a resistive element 1960 corresponds to the dummy storage element 140, a conductor 1944 corresponds to the conductor 144 of FIGS. 1B, 2B, and 3B, and a conductor 1942 corresponds to the conductor 142 of FIGS. 1B, 2B, and 3B. The resistive element 1960 is disposed between the conductors 1942, 1944. One or more vias (or contacts) 1961 connect the resistive element 1960 to the conductor 1942. One or more vias (or contacts) 1963 connect the resistive element 1960 to the conductor 1944. Additional wiring (not shown in FIG. 19A) connects the conductors 1942, 1944 to other circuit elements in the semiconductor device.

The resistive element 1960 is formed of a resistive material that has an electrical conductivity that is less than that of the conductors 1942, 1944. Examples materials for the resistive element 1960 include resistive materials that are compatible with BEOL processes. In some embodiments, the storage elements 120 of the memory cell array 117 include a resistive material and the same resistive material is also used to form the resistive element 1960.

In a particular example, the resistive element 1960 is a MTJ structure as described above in connection with the storage elements 120. In some embodiments, the reference layer and the free layer of the MTJ structure are formed to provide the MTJ structure, i.e., the resistive element 1960, with a given resistivity, e.g., per unit length, thickness, area or the like. The resistive element 1960 has a resistance that is determined at least in part by the overall length, thickness, area, or the like of the resistive element 1960. In some embodiments, the resistive element 1960 is fabricated with a fixed and/or predetermined resistance.

In some embodiments, the overall resistance of the resistor structure 1900A is determined by a combination of factors that include the resistivity of the resistive element 1960, the dimensions of the resistive element 1960, and the number and locations of the vias 1961, 1963. Increasing a via ratio (e.g., increasing a number of vias for the top and bottom side connections to the resistive element 1960) reduces overall resistance by enhancing conductivity. Decreasing top via-to-bottom via spacing reduces the overall resistance by shortening a path through the resistive element 1960.

For example, the overall resistance of the resistor structure 1900A in FIG. 19A is determined in part by the presence of three vias 1961 and three vias 1963. Comparatively, the resistor structure 1900B has only two vias 1961 and two vias 1963, and the distance between the vias 1961, 1963 is greater in the resistor structure 1900B than in the resistor structure 1900A. Thus, assuming a same resistive element 1960 is used in each of the resistor structures 1900A, 1900B, the relatively higher number and closer spacing of the vias 1961, 1963 in the resistor structure 1900A results in a lower overall resistance for the resistor structure 1900A than for the resistor structure 1900B.

Semiconductor devices according to embodiments are thus configurable to have resistor structures 1900A, 1900B with overall resistances that can be set or adjusted not only by resistance of the resistive element 1960 but also by a layout of conductors in various wiring layers, e.g., the conductor 1944 in the wiring layer Mx, the conductor 1942 in the wiring layer Mx-1, and the connecting vias. Further, the conductors 1942, 1944 serve a dual purpose of mitigating loading effects by tuning the area density of conductors in the peripheral circuit 118 relative to conductors in the memory cell array 117, and allowing for integration of resistor structures into the BEOL layers.

FIG. 19B is a schematic cross-sectional view of resistor structures 1900C and 1900D according to some embodiments.

The resistor structure 1900C includes a first MTJ resistive element 1960A and the resistor structure 1900D includes a second MTJ resistive element 1960B. The reference and free layers in the first MTJ resistive element 1960A have a first parallel magnetic moment, and the reference and free layers in the second MTJ resistive element 1960B have a second parallel magnetic moment that is weaker than the first parallel magnetic moment. The stronger parallel magnetic moment of the first MTJ resistive element 1960A leads to reduced resistance in the first MTJ resistive element 1960A relative to the second MTJ resistive element 1960B. Semiconductor devices according to embodiments are thus configurable to have resistor structures 1900C, 1900D with overall resistances that depend on the relative magnetic moments of the reference and free layers. In some embodiments, an MTJ resistor structure that includes an MTJ resistive element with a first parallel magnetic moment has a lower resistance than an MTJ resistor structure that includes an MTJ resistive element with a second, relatively weaker parallel magnetic moment. In some embodiments, an MTJ resistor structure that includes vias of a first size connecting conductors to an MTJ resistive element has a lower resistance than an MTJ resistor structure that includes vias of a second, relatively smaller size. In some embodiments, an MTJ resistor structure that includes a first number of vias connecting conductors to an MTJ resistive element has a lower resistance than an MTJ resistor structure that includes a second, lower number of vias. In some embodiments, an MTJ resistor structure that includes vias on opposite sides of the MTJ resistive element that are spaced apart by a first lateral distance has a lower resistance than an MTJ resistor structure that includes vias that are spaced apart by a second, relatively greater lateral distance.

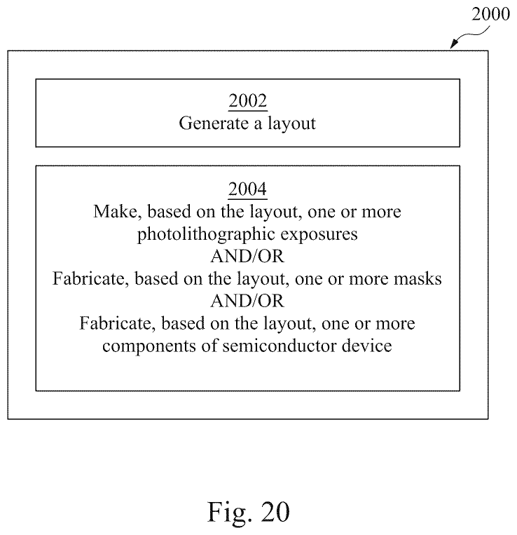

FIG. 20 is a flowchart of a method 2000 of generating a layout and using the layout to manufacture a semiconductor device according to some embodiments.

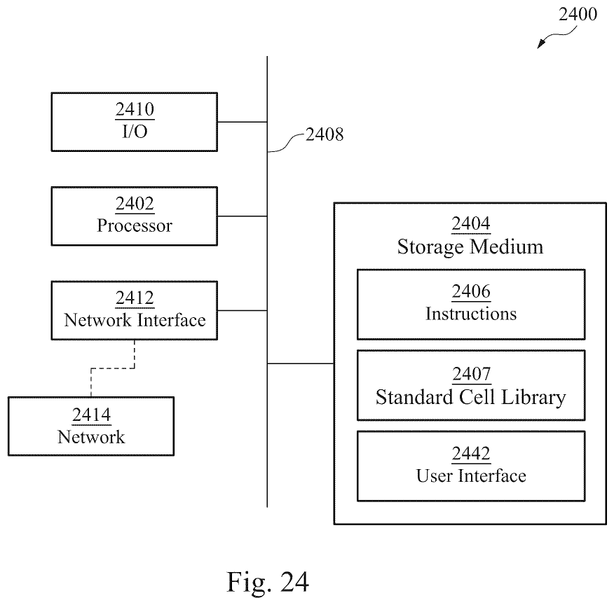

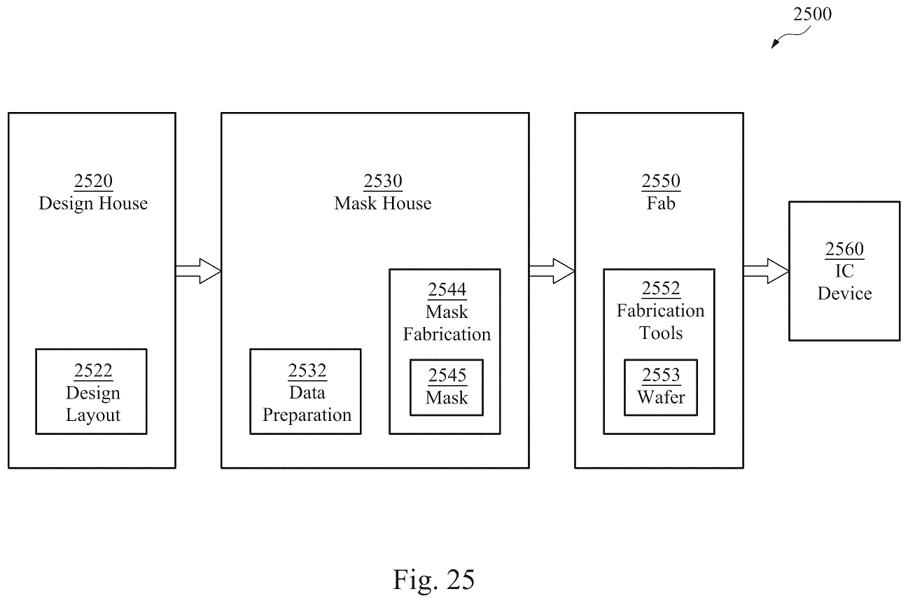

Method 2000 is implementable, for example, using an electronic design automation (EDA) system (see EDA system 2400, discussed below in connection with FIG. 24) and a semiconductor device manufacturing system (see system 2500, discussed below in connection with FIG. 25). Examples of a semiconductor device to be manufactured according to method 2000 include the semiconductor devices disclosed herein. In FIG. 20, method 2000 includes operations 2002˜2004.

At operation 2002, a layout is generated. In some embodiments, operation 2002 for generating a layout includes selecting a standard cell from among a library of standard cells, the library of standard cells including one or more standard cells representing a memory element and one or more standard cells representing a peripheral circuit element having a dummy memory structure. From operation 2002, flow proceeds to operation 2004.

At operation 2004, based on the layout, at least one of (A) one or more photolithographic exposures are made or (B) one or more semiconductor masks are fabricated or (C) one or more components in a layer of a semiconductor device are fabricated.

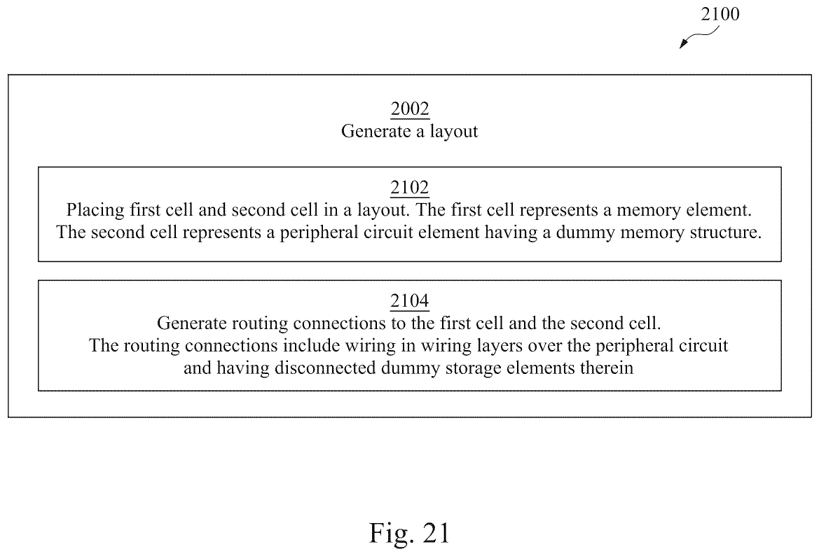

FIG. 21 is a flowchart of a method 2100 of generating a layout according to an embodiment. More particularly, the flowchart of FIG. 21 shows additional operations that demonstrate one example of procedures implementable in operation 2002 of FIG. 20. In FIG. 21, operation 2002 includes operations 2102˜2104.

At operation 2102, the method includes placing a first cell and a second cell in a layout. The first cell represents a memory element. The second cell represents a peripheral circuit element having a dummy memory structure.

At operation 2104, the method includes generating routing connections to the first cell and the second cell. The routing connections include wiring in wiring layers over the peripheral circuit and having disconnected dummy storage elements therein.

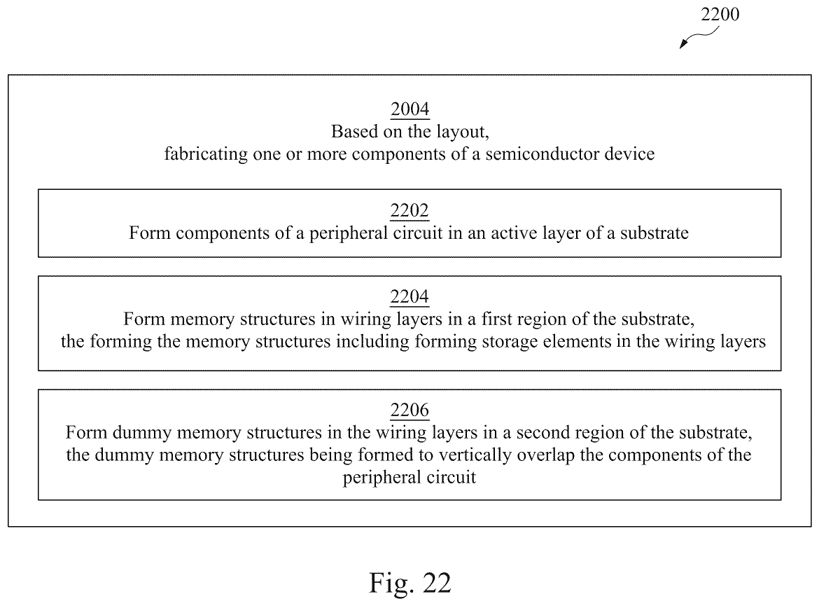

FIG. 22 is a flowchart of a method 2200 of fabricating one or more components of a semiconductor device according to an embodiment. More particularly, the flowchart of FIG. 22 shows additional operations that demonstrate one example of procedures implementable in operation 2004 of FIG. 20. In FIG. 22, operation 2004 includes operations 2202˜2206.

At operation 2202, components of a peripheral circuit are formed in an active layer of a substrate. The peripheral circuit corresponds to the peripheral circuit 118 described above. Examples of the peripheral circuit, components of which are formed in operation 2202, include a WLDRV circuit, a LIO circuit, an MIO circuit, a GIO circuit, a LCTRL circuit, a GCTRL circuit, and an MCTRL circuit.

At operation 2204, memory structures are formed in wiring layers in a first region of the substrate. Forming the memory structures includes forming storage elements in the wiring layers. The memory structures correspond to memory cells of the memory cell array 117. Examples of the memory structures include MIM capacitor structures, RRAM structures, MRAM structures, PCM structures, and other BEOL-compatible storage structures.

At operation 2206, dummy memory structures are formed in the wiring layers in a second region of the substrate. The dummy memory structures are formed to vertically overlap the components of the peripheral circuit formed in operation 2202. The dummy memory structures correspond to MIM capacitor structures, RRAM structures, MRAM structures, PCM structures, and other BEOL-compatible storage structures. In some embodiments, the dummy memory structures are disconnected from one or more vertically overlapping conductors in the wiring layers.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of a semiconductor device manufacturing system discussed below.

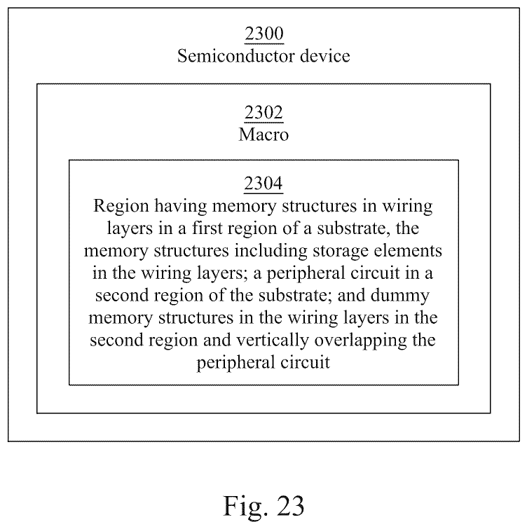

FIG. 23 is a block diagram of a semiconductor device 2300 according to an embodiment. The semiconductor device 2300 corresponds to, e.g., any of the semiconductor devices 100˜1800 described above. In some embodiments, the semiconductor device includes one or more of the resistor structures 1900A˜D described above.

In FIG. 23, the semiconductor device 2300 includes a macro 2302. In some embodiments, the macro 2302 includes one or more of a memory, a power grid, a cell or cells, an inverter, a latch, a buffer, a peripheral circuit or a component thereof, and/or any other type of circuit arrangement that may be represented digitally in a cell library. In some embodiments, the macro 2302 is understood in the context of an analogy to the architectural hierarchy of modular programming, in which subroutines/procedures are called by a main program (or by other subroutines) to carry out a given computational function. In this context, the semiconductor device 2300 uses the macro 2302 to perform one or more given functions. Accordingly, in this context and in terms of architectural hierarchy, the semiconductor device 2300 is analogous to the main program and the macro 2302 is analogous to subroutines/procedures. In some embodiments, the macro 2302 is a soft macro. In some embodiments, the macro 2302 is a hard macro. In some embodiments, the macro 2302 is a soft macro which is described digitally in register-transfer level (RTL) code. In some embodiments, synthesis, placement, and routing have yet to have been performed on the macro 2302 such that the soft macro can be synthesized, placed, and routed for a variety of process nodes. In some embodiments, the macro 2302 is a hard macro which is described digitally in a binary file format (e.g., Graphic Database System II (GDSII) stream format), where the binary file format represents planar geometric shapes, text labels, other information, and the like of one or more layouts of the macro 2302 in hierarchical form. In some embodiments, synthesis, placement, and routing have been performed on the macro 2302 such that the hard macro is specific to a particular process node.

In FIG. 23, the macro 2302 includes a region 2304 that includes memory structures in wiring layers in a first region of a substrate, the memory structures including storage elements in the wiring layers; a peripheral circuit in a second region of the substrate; and dummy memory structures in the wiring layers in the second region and vertically overlapping the peripheral circuit.

In some embodiments, the region 2304 corresponds to a substrate having circuitry formed thereon, in a front-end-of-line (FEOL) fabrication. In the region 2304 above the substrate, various metal layers are stacked with interposed insulating layers in a back end of line (BEOL) fabrication. The BEOL layers provide, among other things, a power network and/or routing for circuitry of the semiconductor device 2300, including the macro 2302 and the region 2304. The BEOL layers include the memory structures and the dummy memory structures.

FIG. 24 is a block diagram of an electronic design automation (EDA) system 2400 according to some embodiments.

In some embodiments, EDA system 2400 includes an APR system. Methods described herein of designing layouts represent wire routing arrangements, in accordance with one or more embodiments, are implementable, for example, using EDA system 2400, in accordance with some embodiments.

In some embodiments, EDA system 2400 is a general purpose computing device including a hardware processor 2402 and a non-transitory, computer-readable storage medium 2404. The computer-readable storage medium 2404, amongst other things, is encoded with, i.e., stores, computer program code 2406, i.e., a set of executable instructions. Execution of instructions 2406 by the processor 2402 represents (at least in part) an EDA tool which implements a portion or all of the methods described herein in accordance with one or more embodiments (hereinafter, the noted processes and/or methods).

The processor 2402 is electrically coupled to the computer-readable storage medium 2404 via a bus 2408. The processor 2402 is also electrically coupled to an I/O interface 2410 by the bus 2408. A network interface 2412 is also electrically connected to processor 2402 via the bus 2408. Network interface 2412 is connected to a network 2414, so that the processor 2402 and the computer-readable storage medium 2404 are capable of connecting to external elements via network 2414. The processor 2402 is configured to execute computer program code 2406 encoded in the computer-readable storage medium 2404 in order to cause the EDA system 2400 to be usable for performing a portion or all of the noted processes and/or methods. In one or more embodiments, the processor 2402 is a central processing unit (CPU), a multi-processor, a distributed processing system, an application specific integrated circuit (ASIC), and/or a suitable processing unit.

In one or more embodiments, the computer-readable storage medium 2404 is an electronic, magnetic, optical, electromagnetic, infrared, and/or a semiconductor system (or apparatus or device). Examples of the computer-readable storage medium 2404 include a semiconductor or solid-state memory, a magnetic tape, a removable computer diskette, a random access memory (RAM), a read-only memory (ROM), a rigid magnetic disk, and/or an optical disk. In one or more embodiments using optical disks, the computer-readable storage medium 2404 includes a compact disk-read only memory (CD-ROM), a compact disk-read/write (CD-R/W), and/or a digital video disc (DVD).

In one or more embodiments, the computer-readable storage medium 2404 stores computer program code 2406 configured to cause the EDA system 2400 (where such execution represents (at least in part) the EDA tool) to be usable for performing a portion or all of the noted processes and/or methods. In one or more embodiments, the computer-readable storage medium 2404 also stores information which facilitates performing a portion or all of the noted processes and/or methods. In one or more embodiments, the computer-readable storage medium 2404 stores a library 2407 of standard cells including such standard cells as disclosed herein.

The EDA system 2400 includes an I/O interface 2410. The I/O interface 2410 is coupled to external circuitry. In one or more embodiments, the I/O interface 2410 includes a keyboard, keypad, mouse, trackball, trackpad, touchscreen, and/or cursor direction keys for communicating information and commands to the processor 2402.

The EDA system 2400 also includes the network interface 2412 coupled to the processor 2402. The network interface 2412 allows the EDA system 2400 to communicate with the network 2414, to which one or more other computer systems are connected. The network interface 2412 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 2400.

The EDA system 2400 is configured to receive information through the I/O interface 2410. The information received through the I/O interface 2410 includes one or more of instructions, data, design rules, libraries of standard cells, and/or other parameters for processing by the processor 2402. The information is transferred to the processor 2402 via the bus 2408. The EDA system 2400 is configured to receive information related to a user interface (UI) through the I/O interface 2410. The information is stored in the computer-readable storage medium 2404 as user interface (UI) 2442.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by the EDA system 2400. In some embodiments, a layout that includes standard cells is generated using a tool such as VIRTUOSO® available from Cadence Design Systems, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 25 is a block diagram of an integrated circuit (IC) manufacturing system 2500, and a semiconductor device manufacturing flow associated therewith, according to some embodiments. In some embodiments, based on a layout, at least one of (A) one or more semiconductor masks or (B) at least one component in a layer of a semiconductor integrated circuit is fabricated using the IC manufacturing system 2500.

In FIG. 25, the IC manufacturing system 2500 includes entities, such as a design house 2520, a mask house 2530, and an IC manufacturer/fabricator (“fab”) 2550, that interact with one another in the design, development, and manufacturing cycles and/or services related to manufacturing an IC device 2560. The entities in the IC manufacturing system 2500 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 2520, the mask house 2530, and the IC fab 2550 are owned by a single larger company. In some embodiments, two or more of the design house 2520, the mask house 2530, and the IC fab 2550 coexist in a common facility and use common resources.

The design house (or design team) 2520 generates an IC design layout 2522. The IC design layout 2522 includes various geometrical patterns designed for an IC device 2560. The geometrical patterns correspond to patterns of metal, oxide, or semiconductor layers that make up the various components of the IC device 2560 to be fabricated. The various layers combine to form various IC features. For example, a portion of the IC design layout 2522 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 2520 implements a formal design procedure to form the IC design layout 2522. The design procedure includes one or more of logic design, physical design or place-and-route operation. The IC design layout 2522 is presented in one or more data files having information of the geometrical patterns. For example, the IC design layout 2522 can be expressed in a GDSII file format or DFII file format.

The mask house 2530 includes mask data preparation 2532 and mask fabrication 2544. The mask house 2530 uses the IC design layout 2522 to manufacture one or more masks 2545 to be used for fabricating the various layers of the IC device 2560 according to the IC design layout 2522. The mask house 2530 performs the mask data preparation 2532, where the IC design layout 2522 is translated into a representative data file (“RDF”). The mask data preparation 2532 provides the RDF to the mask fabrication 2544. The mask fabrication 2544 includes a mask writer. The mask writer converts the RDF to an image on a substrate, such as a mask (reticle) 2545 or a semiconductor wafer 2553. The IC design layout 2522 is manipulated by the mask data preparation 2532 to comply with particular characteristics of the mask writer and/or requirements of the IC fab 2550. In FIG. 25, the mask data preparation 2532 and the mask fabrication 2544 are illustrated as separate elements. In some embodiments, the mask data preparation 2532 and the mask fabrication 2544 can be collectively referred to as mask data preparation.

In some embodiments, the mask data preparation 2532 includes optical proximity correction (OPC) that uses lithography enhancement techniques to compensate for image errors, such as those that can arise from diffraction, interference, other process effects and the like. The OPC adjusts the IC design layout 2522. In some embodiments, the mask data preparation 2532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 2532 includes a mask rule checker (MRC) that checks the IC design layout 2522 that has undergone processes in the OPC with a set of mask creation rules containing geometric and/or connectivity restrictions to ensure sufficient margins, to account for variability in semiconductor manufacturing processes, and the like. In some embodiments, the MRC modifies the IC design layout 2522 to compensate for limitations during the mask fabrication 2544, which may undo part of the modifications performed by OPC in order to meet mask creation rules.

In some embodiments, the mask data preparation 2532 includes lithography process checking (LPC) that simulates processing that will be implemented by the IC fab 2550 to fabricate the IC device 2560. The LPC simulates this processing based on the IC design layout 2522 to create a simulated manufactured device, such as the IC device 2560. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are repeated to further refine the IC design layout 2522.

It should be understood that the above description of the mask data preparation 2532 has been simplified for the purposes of clarity. In some embodiments, the mask data preparation 2532 includes additional features such as a logic operation (LOP) to modify the IC design layout 2522 according to manufacturing rules. Additionally, the processes applied to the IC design layout 2522 during the mask data preparation 2532 may be executed in a variety of different orders.

After the mask data preparation 2532 and during the mask fabrication 2544, a mask 2545 or a group of masks 2545 are fabricated based on the modified IC design layout 2522. In some embodiments, the mask fabrication 2544 includes performing one or more lithographic exposures based on the IC design layout 2522. In some embodiments, an electron-beam (e-beam) or a mechanism of multiple e-beams is used to form a pattern on a mask (photomask or reticle) 2545 based on the modified IC design layout 2522. The mask 2545 can be formed in various technologies. In some embodiments, the mask 2545 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 2545 includes a transparent substrate (e.g., fused quartz) and an opaque material (e.g., chromium) coated in the opaque regions of the binary mask. In another example, the mask 2545 is formed using a phase shift technology. In a phase shift mask (PSM) version of the mask 2545, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 2544 is used in a variety of processes. For example, such a mask(s) is used in an ion implantation process to form various doped regions in a semiconductor wafer 2553, in an etching process to form various etching regions in the semiconductor wafer 2553, and/or in other suitable processes.

The IC fab 2550 is an IC fabrication business that includes one or more manufacturing facilities for the fabrication of a variety of different IC products. In some embodiments, the IC fab 2550 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 2550 includes fabrication tools 2552 configured to execute various manufacturing operations on semiconductor wafer 2553 such that the IC device 2560 is fabricated in accordance with the mask(s), e.g., the mask 2545. In various embodiments, the fabrication tools 2552 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 2550 uses the mask(s) 2545 fabricated by the mask house 2530 to fabricate the IC device 2560. Thus, the IC fab 2550 at least indirectly uses the IC design layout 2522 to fabricate the IC device 2560. In some embodiments, the semiconductor wafer 2553 is fabricated by the IC fab 2550 using the mask(s) 2545 to form the IC device 2560. In some embodiments, the IC fabrication includes performing one or more lithographic exposures based at least indirectly on the IC design layout 2522. The semiconductor wafer 2553 includes a silicon substrate or other proper substrate having material layers formed thereon. The semiconductor wafer 2553 further includes one or more of various doped regions, dielectric features, multilevel interconnects, and the like (formed at subsequent manufacturing steps).

Details regarding an integrated circuit (IC) manufacturing system (e.g., the IC manufacturing system 2500 of FIG. 25), and an IC manufacturing flow associated therewith are found, e.g., in U.S. Pat. No. 9,256,709, granted Feb. 9, 2016, U.S. Pre-Grant Publication No. 2015/0278429, published Oct. 1, 2015, U.S. Pre-Grant Publication No. 2014/0040838, published Feb. 6, 2014, and U.S. Pat. No. 7,260,442, granted Aug. 21, 2007, the entireties of each of which are hereby incorporated by reference.

In some embodiments, a semiconductor device includes memory structures in wiring layers in a first region of a substrate, the memory structures including storage elements in the wiring layers; a peripheral circuit in a second region of the substrate; and dummy memory structures in the wiring layers in the second region and vertically overlapping the peripheral circuit.

In some embodiments, the dummy memory structures include dummy storage elements in the wiring layers in the second region. In some embodiments, the semiconductor device further includes first transistors in an active layer in the first region, the storage elements vertically overlapping the first transistors in the first region; and second transistors in the active layer in the second region, the dummy memory structures vertically overlapping the second transistors. In some embodiments, the dummy memory structures each include a dummy storage element in the wiring layers in the second region; a first conductor in a first wiring layer under the dummy storage element; and a second conductor in a second wiring layer over the dummy storage element. In some embodiments, the dummy storage elements are electrically disconnected from at least one of the first or second conductors. In some embodiments, the semiconductor device further includes a third region between the first region and the second region, the third region being free of the storage elements and free of the dummy storage elements. In some embodiments, the semiconductor device further includes a third region between the first region and the second region. In some embodiments, the memory structures each include a first conductor in a first wiring layer and vertically overlapping the storage element; and a second conductor in a second wiring layer and vertically overlapping the storage element. In some embodiments, the dummy memory structures each include a dummy storage element in the wiring layers in the second region; a third conductor in the first wiring layer and vertically overlapping the dummy storage element; and a fourth conductor in the second wiring layer and vertically overlapping the dummy storage element. In some embodiments, the third region includes an insulating material in the first wiring layer; and a fifth conductor in the second wiring layer. In some embodiments, the first wiring layer has a first area density in the first region, the first wiring layer has a second area density in the second region, the first wiring layer has a third area density in the third region, and the third area density is less than each of the first area density and the second area density. In some embodiments, the third region is free of conductors in the first wiring layer such that the third area density is zero. In some embodiments, the first area density is equal to or about equal to the second area density.

In some embodiments, a method of fabricating a semiconductor device includes forming components of a peripheral circuit in an active layer of a substrate; forming memory structures in wiring layers in a first region of the substrate, the forming the memory structures including forming storage elements the wiring layers; and forming dummy memory structures in the wiring layers in a second region of the substrate, the dummy memory structures being formed to vertically overlap the components of the peripheral circuit.

In some embodiments, the method further includes forming first transistors in the active layer in the first region, In some embodiments, the forming the components of a peripheral circuit includes forming second transistors in the active layer, the forming dummy memory structures includes forming dummy storage elements in the wiring layers, the storage elements are formed to vertically overlap the first transistors in the first region, and the dummy storage elements are formed to vertically overlap the second transistors in the second region. In some embodiments, the forming dummy memory structures includes forming a dummy storage element in the wiring layers in the second region; forming a first conductor in a first wiring layer under the dummy storage element; and forming a second conductor in a second wiring layer over the dummy storage element, and the dummy storage elements are formed to be electrically disconnected from at least one of the first or second conductors. In some embodiments, a third region between the first region and the second region is formed to be free of the storage elements and free of the dummy storage elements. In some embodiments, the forming the memory structures includes forming a first conductor in a first wiring layer and vertically overlapping one of the storage elements; and forming a second conductor vertically in a second wiring layer and overlapping one of the storage elements, and the forming the dummy memory structures includes forming a dummy storage element in the wiring layers in the second region; forming a third conductor in the first wiring layer and vertically overlapping the dummy storage element; and forming a fourth conductor in the second wiring layer and vertically overlapping the dummy storage element. In some embodiments, the method further includes forming a third region, including forming an insulating material in the first wiring layer in a third region; and forming a fifth conductor in the second wiring layer. In some embodiments, the first wiring layer is formed to have a first area density in the first region, the first wiring layer is formed to have a second area density in the second region, the first wiring layer is formed to have a third area density in the third region, and the third area density is less than each of the first area density and the second area density. In some embodiments, the third region is formed to be free of conductors in the first wiring layer such that the third area density is zero. In some embodiments, the first area density is formed to be equal to or about equal to the second area density.

In some embodiments, a semiconductor device includes memory cells in a first region of a substrate, the memory cells including magnetic tunnel junction (MTJ) storage elements in wiring layers in the first region of the substrate; a peripheral circuit in a second region of the substrate; and resistors in the second region of the substrate, the resistors including MTJ resistor elements in the wiring layers in the second region and vertically overlapping the peripheral circuit

In some embodiments, the MTJ resistor elements have fixed resistance values. In some embodiments, the memory cells each include a first conductor in a first wiring layer and vertically overlapping the MTJ storage element; and a second conductor in a second wiring layer and vertically overlapping the MTJ storage element. In some embodiments, the resistors each include a third conductor in the first wiring layer and vertically overlapping the MTJ resistor element; and a fourth conductor in the second wiring layer and vertically overlapping the MTJ resistor element. In some embodiments, the resistors each include a first conductor contacting and vertically overlapping the MTJ resistor element; and a second conductor contacting and vertically overlapping the MTJ resistor element, the resistors include a first resistor having a first resistance and a second resistor having a second resistance different from the first resistance, the first and second conductors of the first resistor are spaced apart by a first distance, and the first and second conductors of the second resistor are spaced apart by a second distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
memory structures in wiring layers in a first region of a substrate, the memory structures including storage elements in the wiring layers;
a peripheral circuit in a second region of the substrate; and
dummy memory structures in the wiring layers in the second region and vertically overlapping the peripheral circuit.

2. The semiconductor device of claim 1, wherein the dummy memory structures include dummy storage elements in the wiring layers in the second region, the semiconductor device further comprising:
first transistors in an active layer in the first region, the storage elements vertically overlapping the first transistors in the first region; and
second transistors in the active layer in the second region, the dummy memory structures vertically overlapping the second transistors.

3. The semiconductor device of claim 1, wherein:
the dummy memory structures each include:
a dummy storage element in the wiring layers in the second region;
a first conductor in a first wiring layer under the dummy storage element; and
a second conductor in a second wiring layer over the dummy storage element, and
the dummy storage elements are electrically disconnected from at least one of the first or second conductors.

4. The semiconductor device of claim 3, further comprising a third region between the first region and the second region, the third region being free of the storage elements and free of the dummy storage elements.

5. The semiconductor device of claim 1, further comprising a third region between the first region and the second region, wherein:
the memory structures each include:
a first conductor in a first wiring layer and vertically overlapping the storage element; and
a second conductor in a second wiring layer and vertically overlapping the storage element, and
the dummy memory structures each include:
a dummy storage element in the wiring layers in the second region;
a third conductor in the first wiring layer and vertically overlapping the dummy storage element; and
a fourth conductor in the second wiring layer and vertically overlapping the dummy storage element, and
the third region includes:
an insulating material in the first wiring layer; and
a fifth conductor in the second wiring layer.

6. The semiconductor device of claim 5, wherein:
the first wiring layer has a first area density in the first region,
the first wiring layer has a second area density in the second region,
the first wiring layer has a third area density in the third region, and
the third area density is less than each of the first area density and the second area density.

7. The semiconductor device of claim 6, wherein the third region is free of conductors in the first wiring layer such that the third area density is zero.

8. The semiconductor device of claim 6, wherein the first area density is equal to or about equal to the second area density.

9. A method of fabricating a semiconductor device, comprising:
forming components of a peripheral circuit in an active layer of a substrate;
forming memory structures in wiring layers in a first region of the substrate, the forming the memory structures including forming storage elements in the wiring layers; and
forming dummy memory structures in the wiring layers in a second region of the substrate, the dummy memory structures being formed to vertically overlap the components of the peripheral circuit.

10. The method of claim 9, further comprising:
forming first transistors in the active layer in the first region;
wherein:
the forming the components of a peripheral circuit includes forming second transistors in the active layer,
the forming dummy memory structures includes forming dummy storage elements in the wiring layers,
the storage elements are formed to vertically overlap the first transistors in the first region, and
the dummy storage elements are formed to vertically overlap the second transistors in the second region.

11. The method of claim 9, wherein:
the forming dummy memory structures includes:
forming a dummy storage element in the wiring layers in the second region;
forming a first conductor in a first wiring layer under the dummy storage element; and
forming a second conductor in a second wiring layer over the dummy storage element, and
the dummy storage elements are formed to be electrically disconnected from at least one of the first or second conductors.

12. The method of claim 11, wherein a third region between the first region and the second region is formed to be free of the storage elements and free of the dummy storage elements.

13. The method of claim 9, wherein:
the forming the memory structures includes:
forming a first conductor in a first wiring layer and vertically overlapping one of the storage elements; and
forming a second conductor in a second wiring layer and vertically overlapping one of the storage elements, and
the forming the dummy memory structures includes:
forming a dummy storage element in the wiring layers in the second region;
forming a third conductor in the first wiring layer and vertically overlapping the dummy storage element; and
forming a fourth conductor in the second wiring layer and vertically overlapping the dummy storage element,
the method further comprising forming a third region, including:
forming an insulating material in the first wiring layer in a third region; and
forming a fifth conductor in the second wiring layer.

14. The method of claim 13, wherein:
the first wiring layer is formed to have a first area density in the first region,
the first wiring layer is formed to have a second area density in the second region,
the first wiring layer is formed to have a third area density in the third region, and
the third area density is less than each of the first area density and the second area density.

15. The method of claim 14, wherein the third region is formed to be free of conductors in the first wiring layer such that the third area density is zero.

16. The method of claim 14, wherein the first area density is formed to be equal to or about equal to the second area density.

17. A semiconductor device, comprising:
memory cells in a first region of a substrate, the memory cells including magnetic tunnel junction (MTJ) storage elements in wiring layers in the first region of the substrate;
a peripheral circuit in a second region of the substrate; and
resistors in the second region of the substrate, the resistors including MTJ resistor elements in the wiring layers in the second region and vertically overlapping the peripheral circuit.

18. The semiconductor device of claim 17, wherein the MTJ resistor elements have fixed resistance values.

19. The semiconductor device of claim 17, wherein:
the memory cells each include:
a first conductor in a first wiring layer and vertically overlapping the MTJ storage element; and
a second conductor in a second wiring layer and vertically overlapping the MTJ storage element, and
the resistors each include:
a third conductor in the first wiring layer and vertically overlapping the MTJ resistor element; and
a fourth conductor in the second wiring layer and vertically overlapping the MTJ resistor element.

20. The semiconductor device of claim 17, wherein:
the resistors each include:
a first conductor contacting and vertically overlapping the MTJ resistor element; and
a second conductor contacting and vertically overlapping the MTJ resistor element,
the resistors include a first resistor having a first resistance and a second resistor having a second resistance different from the first resistance,
the first and second conductors of the first resistor are spaced apart by a first distance, and
the first and second conductors of the second resistor are spaced apart by a second distance.
